(19) United States
(12) Patent Application Publication
(10) Pub. No.: US 2025/0239992 A1
(43) Pub. Date: Jul. 24, 2025

(54) ACOUSTIC WAVE DEVICE AND ACOUSTIC WAVE ELEMENT

(71) Applicant: Murata Manufacturing Co., Ltd., Nagaokakyo-shi (JP)

(72) Inventor: Kazuhiro TAKIGAWA, Nagaokakyo-shi (JP)

(21) Appl. No.: 19/173,949

(22) Filed: Apr. 9, 2025

Related U.S. Application Data
(63) Continuation of application No. PCT/JP2023/037030, filed on Oct. 12, 2023.

(30) Foreign Application Priority Data
Oct. 19, 2022 (JP) 2022-167842

(51) Int. Cl. H03H 9/25; H03H 9/02

(52) U.S. Cl. CPC H03H 9/25; H03H 9/02842; H03H 9/02992

(57) ABSTRACT

An acoustic wave device includes a piezoelectric substrate, an IDT electrode on the piezoelectric substrate and including first and second busbars including first and second interdigitated electrode fingers, and reflectors on the piezoelectric substrate facing each other across the IDT electrode. In the IDT electrode, a pair of regions outward of first and second base ends of the first and second electrode fingers are a pair of outer regions, and regions extending from the pair of outer regions are a pair of extended outer regions. Each of the reflectors includes a pair of reflector busbars facing each other and reflector electrode fingers electrically connected to the pair of reflector busbars. Each of the reflector busbars includes a plurality of reflector connection electrodes in a portion of the reflector located in one of the extended outer regions and directly or indirectly connected to the reflector electrode fingers.

### CROSS REFERENCE TO RELATED APPLICATIONS

This application claims the benefit of priority to Japanese Patent Application No. 2022-167842 filed on Oct. 19, 2022 and is a Continuation Application of PCT Application No. PCT/JP2023/037030 filed on Oct. 12, 2023. The entire contents of each application are hereby incorporated herein by reference.

### BACKGROUND OF THE INVENTION

### 1. Field of the Invention

The present invention relates to acoustic wave devices and acoustic wave elements including the acoustic wave devices providing acoustic wave resonators.

### 2. Description of the Related Art

An acoustic wave device has heretofore been widely used as, for example, a filter for a mobile phone. International Publication No. 2015/182522 discloses an example of the acoustic wave device. In this acoustic wave device, an interdigital transducer (IDT) is provided on a piezoelectric substrate. In the IDT, a central region, a low acoustic velocity region, and a high acoustic velocity region are disposed in this order from an inner side to an outer side in a direction in which a plurality of electrode fingers extend. Such regions with different acoustic velocities disposed in the direction in which the plurality of electrode fingers extend reduce or prevent a transverse mode.

### SUMMARY OF THE INVENTION

There is, however, a possibility that an increase in return loss cannot be sufficiently prevented in the acoustic wave device of International Publication No. 2015/182522.

Example embodiments of the present invention provide acoustic wave devices each capable of preventing an increase in return loss.

An acoustic wave device according to an example embodiment of the present invention includes a piezoelectric substrate, an IDT electrode on the piezoelectric substrate and including a first busbar and a second busbar facing each other, and a plurality of first electrode fingers and a plurality of second electrode fingers interdigitated with each other, and a pair of reflectors on the piezoelectric substrate and facing each other across the IDT electrode in a second direction, where a first direction is a direction in which the plurality of first electrode fingers and the plurality of second electrode fingers extend and the second direction is a direction orthogonal to the first direction, wherein the plurality of first electrode fingers each include a first base end connected to the first busbar, and the plurality of second electrode fingers each include a second base end connected to the second busbar, in the IDT electrode, a pair of regions outward of first and second base ends of the first and second electrode fingers in the first direction are a pair of outer regions, and regions extending from the pair of outer regions in the second direction are a pair of extended outer regions, each of the reflectors includes a pair of reflector busbars facing each other and a plurality of reflector electrode fingers electrically connected to the pair of reflector busbars, each of the reflector busbars includes a plurality of reflector connection electrodes provided in a portion of the reflector located in one of the extended outer regions and directly or indirectly connected to the plurality of reflector electrode fingers, a region of the reflector extending in the second direction where the plurality of reflector connection electrodes are located is a connection electrode formation region, and when a dimension of one period is twice a center-to-center distance in the second direction between adjacent ones of the reflector electrode fingers, and a ratio of a portion of the piezoelectric substrate covered with a metal of the reflector on a virtual line of the dimension of one period extending in the second direction is a metallization ratio, the connection electrode formation region of at least one of the reflector busbars of at least one of the reflectors includes a portion where the metallization ratio is different in at least one of the first direction and the second direction.

An acoustic wave element according to an example embodiment of the present invention includes a first acoustic wave resonator that is the acoustic wave device according to the above-described example embodiment of the present invention, and a second acoustic wave resonator. The second acoustic wave resonator shares the piezoelectric substrate with the first acoustic wave resonator, the second acoustic wave resonator includes an IDT electrode including a plurality of electrode fingers provided on the piezoelectric substrate separately from the first acoustic wave resonator, and a pair of reflectors provided on the piezoelectric substrate so as to face each other across the IDT electrode, each of the reflectors of the second acoustic wave resonator includes a pair of reflector busbars facing each other and a plurality of reflector electrode fingers electrically connected to the pair of reflector busbars, each of the reflector busbars of the second acoustic wave resonator includes a plurality of reflector connection electrodes directly or indirectly connected to the plurality of reflector electrode fingers, in the second acoustic wave resonator, when a first direction is a direction in which the plurality of electrode fingers of the IDT electrode extend and a second direction is a direction orthogonal to the first direction, a region of the reflector of the second acoustic wave resonator extending in the second direction where the plurality of reflector connection electrodes are located is a connection electrode formation region, when one of the reflectors of the first acoustic wave resonator is a first reflector, one of the reflectors of the second acoustic wave resonator is a second reflector, one of the connection electrode formation regions of the first reflector is a first connection electrode formation region, another of the connection electrode formation regions of the first reflector is a second connection electrode formation region, one of the connection electrode formation regions of the second reflector is a third connection electrode formation region, and another of the connection electrode formation regions of the second reflector is a fourth connection electrode formation region, the first connection electrode formation region and the third connection electrode formation region are adjacent to each other in the second direction of the first acoustic wave resonator, and the second connection electrode formation region and the fourth connection electrode formation region are adjacent to each other in the second direction of the first acoustic wave resonator, each of the connection electrode formation regions of the first reflector includes a first adjacent portion that is a portion including an edge portion on a second reflector side in the connection electrode formation region and a dimension thereof in the second direction of the first acoustic wave resonator is a dimension of one period or more, and each of the connection electrode formation regions of the second reflector includes a second adjacent portion that is a portion including an edge portion on a first reflector side in the connection electrode formation region and a dimension thereof in the second direction of the second acoustic wave resonator is the dimension of one period or more, and a relationship of magnitude of the metallization ratio of the first adjacent portion in the second connection electrode formation region to the metallization ratio of the first adjacent portion in the first connection electrode formation region in the first reflector is different from a relationship of magnitude of the metallization ratio of the second adjacent portion in the fourth connection electrode formation region to the metallization ratio of the second adjacent portion in the third connection electrode formation region in the second reflector.

The acoustic wave devices according to example embodiments of the present invention prevent increases in return loss.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a plan view of an acoustic wave device according to a first example embodiment of the present invention.

FIG. 2 is a plan view showing the vicinity of a second reflector busbar of a reflector according to the first example embodiment of the present invention.

FIG. 3 is a plan view of an acoustic wave device according to a comparative example.

FIG. 4 is a graph showing impedance frequency characteristics of the acoustic wave device according to the first example embodiment of the present invention.

FIG. 5 is a graph showing return loss of the acoustic wave devices according to the first example embodiment of the present invention and the comparative example.

FIG. 6 is a graph showing return loss of the acoustic wave devices according to the first example embodiment of the present invention and the comparative example in a frequency range different from that of FIG. 5.

FIG. 7 is a graph showing the relationship between the number of reflector connection electrodes, every other of which is withdrawn, and a Q value in the acoustic wave device according to the first example embodiment of the present invention.

FIG. 8 is a schematic elevational sectional view of an acoustic wave device according to a modification of the first example embodiment of the present invention.

FIG. 9 is a plan view showing the vicinity of a second reflector busbar of a reflector according to a second example embodiment of the present invention.

FIG. 10 is a graph showing return loss of acoustic wave devices according to the second example embodiment of the present invention and a comparative example.

FIG. 11 is a graph showing return loss of the acoustic wave devices according to the second example embodiment of the present invention and the comparative example in a frequency range different from that of FIG. 10.

FIG. 12 is a graph showing the relationship between the number of reflector connection electrodes, every other of which is withdrawn, and a Q value in the acoustic wave device according to the second example embodiment of the present invention.

FIG. 13 is a plan view showing the vicinity of a second reflector busbar of a reflector according to a third example embodiment of the present invention.

FIG. 14 is a graph showing the relationship between the number of reflector connection electrodes, every other of which is withdrawn, and a Q value in an acoustic wave device according to the third example embodiment of the present invention.

FIG. 15 is a plan view showing the vicinity of a second reflector busbar of a reflector according to a fourth example embodiment of the present invention.

FIG. 16 is a graph showing return loss of acoustic wave devices according to the fourth example embodiment of the present invention and a comparative example.

FIG. 17 is a graph showing return loss of the acoustic wave devices according to the fourth example embodiment of the present invention and the comparative example in a frequency range different from that of FIG. 16.

FIG. 18 is a graph showing the relationship between the number of reflector connection electrodes, every other of which is withdrawn, and a Q value in the acoustic wave device according to the fourth example embodiment of the present invention.

FIG. 19 is a plan view showing the vicinity of a second reflector busbar of a reflector according to a fifth example embodiment of the present invention.

FIG. 20 is a graph showing return loss of acoustic wave devices according to the fifth example embodiment of the present invention and a comparative example.

FIG. 21 is a graph showing return loss of the acoustic wave devices according to the fifth example embodiment of the present invention and the comparative example in a frequency range different from that of FIG. 20.

FIG. 22 is a graph showing the relationship between the number of reflector connection electrodes, every other of which is withdrawn, and a Q value in the acoustic wave device according to the fifth example embodiment of the present invention.

FIG. 23 is a plan view showing the vicinity of a second reflector busbar of a reflector according to a sixth example embodiment of the present invention.

FIG. 24 is a plan view showing the vicinity of a second reflector busbar of a reflector according to a seventh example embodiment of the present invention.

FIG. 25 is a plan view showing the vicinity of a second reflector busbar of a reflector according to an eighth example embodiment of the present invention.

FIG. 26 is a plan view showing the vicinity of a second reflector busbar of a reflector according to a ninth example embodiment of the present invention.

FIG. 27 is a graph showing return loss of acoustic wave devices according to the sixth to ninth example embodiments of the present invention and a comparative example.

FIG. 28 is a graph showing return loss of the acoustic wave devices according to the sixth to ninth example embodiments of the present invention and the comparative example in a frequency range different from that of FIG. 27.

FIG. 29 is a partially enlarged schematic plan view showing the vicinity of a first busbar and a second busbar in an IDT electrode according to a tenth example embodiment of the present invention.

FIG. 30 is a partially enlarged schematic plan view showing the vicinity of a first busbar and a second busbar in an IDT electrode according to an eleventh example embodiment of the present invention.

FIG. 31 is a plan view of an acoustic wave element according to a twelfth example embodiment of the present invention.

FIG. 32 is an enlarged plan view showing the vicinity of a first reflector and a second reflector according to the twelfth example embodiment of the present invention.

FIG. 33 is a schematic plan view of an acoustic wave element including two acoustic wave resonators of the comparative example.

FIG. 34 is a graph showing attenuation frequency characteristics near the high-frequency side of a pass band in a filter device using the acoustic wave element including two acoustic wave resonators of the comparative example.

FIG. 35 is a schematic plan view of an acoustic wave element of the related art.

FIG. 36 is a schematic plan view showing acoustic waves excited and propagated in a first acoustic wave resonator and a second acoustic wave resonator according to the twelfth example embodiment of the present invention.

FIG. 37 is an enlarged plan view showing the vicinity of a first reflector and a second reflector according to a thirteenth example embodiment of the present invention.

FIG. 38 is an enlarged plan view showing the vicinity of a first reflector and a second reflector according to a fourteenth example embodiment of the present invention.

### DETAILED DESCRIPTION OF THE EXAMPLE EMBODIMENTS

The present invention will be clarified by describing specific example embodiments of the present invention with reference to the drawings.

Note that each example embodiment described in this specification is illustrative, and partial substitution or combination of configurations described in different example embodiments is possible.

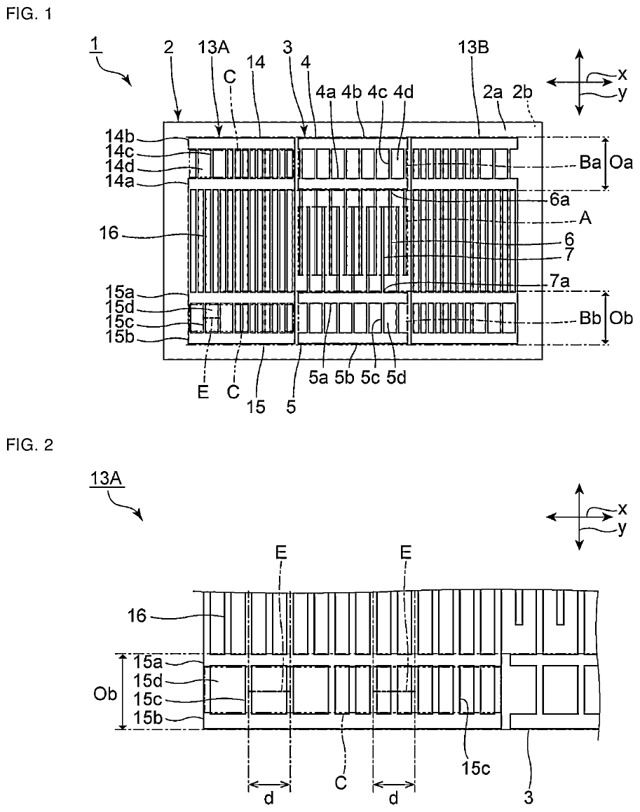

FIG. 1 is a plan view of an acoustic wave device according to a first example embodiment of the present invention.

An acoustic wave device 1 includes a piezoelectric substrate 2. The piezoelectric substrate 2 is a substrate having piezoelectricity. Specifically, in this example embodiment, the piezoelectric substrate 2 is a substrate made only of a piezoelectric material. However, the piezoelectric substrate 2 may be a multilayer substrate including a piezoelectric layer. In this example embodiment, lithium niobate preferably is used as the piezoelectric material of the piezoelectric substrate 2, for example. Note that the piezoelectric material is not limited to the above, and lithium tantalate, zinc oxide, aluminum nitride, quartz, PZT (lead zirconate titanate) or the like can also be used, for example.

The piezoelectric substrate 2 includes a first main surface 2a and a second main surface 2b. The first main surface 2a and the second main surface 2b face each other. An IDT electrode 3 is provided on the first main surface 2a of the piezoelectric substrate 2. By applying an alternating current voltage to the IDT electrode 3, an acoustic wave is excited.

The IDT electrode 3 includes a first busbar 4, a second busbar 5, a plurality of first electrode fingers 6, and a plurality of second electrode fingers 7. The first busbar 4 and the second busbar 5 face each other. The plurality of first electrode fingers 6 each include its one end connected to the first busbar 4. The plurality of second electrode fingers 7 each include its one end connected to the second busbar 5. The plurality of first electrode fingers 6 and the plurality of second electrode fingers 7 interdigitate with each other. The first electrode fingers 6 and the second electrode fingers 7 may be hereinafter simply referred to as electrode fingers.

The plurality of electrode fingers each include a base end and a leading end. More specifically, a first base end 6a is a portion of each of the plurality of first electrode fingers 6 that is connected to the first busbar 4. A second base end 7a is a portion of each of the plurality of second electrode fingers 7 that is connected to the second busbar 5.

Hereinafter, a first direction y is the direction in which the plurality of first electrode fingers 6 and the plurality of second electrode fingers 7 extend, and a second direction x is the direction orthogonal to the first direction y. In this example embodiment, the second direction x is parallel to an acoustic wave propagation direction. An intersection region A is the region where adjacent first electrode fingers 6 and second electrode fingers 7 overlap each other when the IDT electrode 3 is viewed in the second direction x.

The first busbar 4 includes a plurality of cavities 4d provided in the second direction x. Specifically, the first busbar 4 includes an inner busbar portion 4a, an outer busbar portion 4b, and a plurality of connection electrodes 4c. The inner busbar portion 4a is located on the inner side in the first direction y than the cavities 4d and the outer busbar portion 4b. More specifically, the inner busbar portion 4a is located closer to the intersection region A than the cavities 4d and the outer busbar portion 4b. The inner busbar portion 4a and the outer busbar portion 4b are connected to each other by the plurality of connection electrodes 4c. In this example embodiment, the plurality of connection electrodes 4c extend parallel to the first direction y. The plurality of cavities 4d are cavities surrounded by the inner busbar portion 4a, the plurality of connection electrodes 4c, and the outer busbar portion 4b. Each connection electrode 4c is provided on the extension line of each first electrode finger 6, and is not provided on the extension line of each second electrode finger 7.

The second busbar 5 also has the same configuration as that of the first busbar 4. The second busbar 5 includes a plurality of cavities 5d provided in the second direction x. The second busbar 5 includes an inner busbar portion 5a, an outer busbar portion 5b, and a plurality of connection electrodes 5c.

A pair of reflectors 13A and 13B are provided on the piezoelectric substrate 2. The reflectors 13A and 13B are arranged so as to face each other across the IDT electrode 3 in the second direction x.

The IDT electrode 3 includes a pair of outer regions. The pair of outer regions are specifically a first outer region Ba and a second outer region Bb. The first outer region Ba is located on the outer side in the first direction y than the first base ends 6a of the plurality of first electrode fingers 6. The second outer region Bb is located on the outer side in the first direction y than the second base ends 7a of the plurality of second electrode fingers 7. More specifically, the first outer region Ba is a region where the first busbar 4 is provided. The second outer region Bb is a region where the second busbar 5 is provided.

The acoustic wave device 1 includes a pair of extended outer regions. The pair of extended outer regions are specifically a first extended outer region Oa and a second extended outer region Ob. The first extended outer region Oa is a region obtained by extending the first outer region Ba in the second direction x. The second extended outer region Ob is a region obtained by extending the second outer region Bb in the second direction x. The pair of extended outer regions are included not only in the IDT electrode 3 but also in the pair of reflectors.

The reflector 13A includes a pair of reflector busbars and a plurality of reflector electrode fingers 16. The pair of reflector busbars are specifically a first reflector busbar 14 and a second reflector busbar 15. The first reflector busbar 14 and the second reflector busbar 15 face each other. The plurality of reflector electrode fingers 16 are electrically connected to the first reflector busbar 14 and the second reflector busbar 15.

The first reflector busbar 14 includes a plurality of cavities 14d provided in the second direction x. Specifically, the first reflector busbar 14 includes an inner reflector busbar portion 14a, an outer reflector busbar portion 14b, and a plurality of reflector connection electrodes 14c. The inner reflector busbar portion 14a is located on the inner side in the first direction y than the cavities 14d and the outer reflector busbar portion 14b. More specifically, the inner reflector busbar portion 14a is located closer to the plurality of reflector electrode fingers 16 than the cavities 14d and the outer reflector busbar portion 14b. The inner reflector busbar portion 14a and the outer reflector busbar portion 14b are connected to each other by the plurality of reflector connection electrodes 14c. In this example embodiment, the plurality of reflector connection electrodes 14c extend parallel to the first direction y. The plurality of cavities 14d are cavities surrounded by the inner reflector busbar portion 14a, the plurality of reflector connection electrodes 14c, and the outer reflector busbar portion 14b.

Similarly, the second reflector busbar 15 also includes a plurality of cavities 15d provided in the second direction x. The second reflector busbar 15 includes an inner reflector busbar portion 15a, an outer reflector busbar portion 15b, and a plurality of reflector connection electrodes 15c.

FIG. 2 is a plan view showing the vicinity of the second reflector busbar of the reflector according to the first example embodiment.

The second reflector busbar 15 includes a connection electrode formation region C. Specifically, the connection electrode formation region C is a region extending in the second direction x, where the plurality of reflector connection electrodes 15c are located. The connection electrode formation region C is located between the inner reflector busbar portion 15a and the outer reflector busbar portion 15b.

In this example embodiment, all of the reflector electrode fingers 16 are connected to the inner reflector busbar portion 15a. The reflector connection electrodes 15c are provided on the respective extension lines of some of the reflector electrode fingers 16. In the acoustic wave device 1, the reflector electrode fingers 16 are provided on the extension lines of all the reflector connection electrodes 15c. Each reflector connection electrode 15c is indirectly connected to each reflector electrode finger 16 through the inner reflector busbar portion 15a. More specifically, one end of the reflector connection electrode 15c is connected to the inner reflector busbar portion 15a, and one end of the reflector electrode finger 16 is connected to the inner reflector busbar portion 15a. Note that the reflector electrode finger 16 does not necessarily have to be located on the extension line of the reflector connection electrode 15c. In this case, again, each reflector connection electrode 15c is indirectly connected to each reflector electrode finger 16 through the inner reflector busbar portion 15a.

Assuming that a center-to-center distance between adjacent reflector connection electrodes 15c in the second direction x is a connection electrode pitch, the connection electrode formation region C includes a portion where the connection electrode pitch is wide and a portion where the connection electrode pitch is narrow. More specifically, the portion where the connection electrode pitch is wide in the connection electrode formation region C is farther from the IDT electrode 3 than the portion where the connection electrode pitch is narrow.

More specifically, in the portion closer to the IDT electrode 3 in the second direction x, each reflector connection electrode 15c is provided on the extension line of each reflector electrode finger 16. On the other hand, in the portion farther from the IDT electrode 3, each reflector connection electrode 15c is provided on the extension line of every other reflector electrode finger 16. Specifically, the configuration of this portion corresponds to a configuration having every other reflector connection electrode 15c withdrawn from the reflector connection electrodes 15c provided on the extension lines of all the reflector electrode fingers 16. This configuration will be hereinafter simply referred to as a configuration in which every other reflector connection electrode 15c is withdrawn. For example, the configuration shown in FIG. 2 corresponds to a configuration in which every other reflector connection electrode 15c, that is, three reflector connection electrodes 15c in total, including the reflector connection electrode 15c located second farthest from the IDT electrode 3, are withdrawn. The number of reflector connection electrodes 15c to be withdrawn is not limited to the above.

As shown in FIG. 1, the first reflector busbar 14 also has the same configuration. A connection electrode formation region C in the first reflector busbar 14 includes a portion where the connection electrode pitch is wide and a portion where the connection electrode pitch is narrow. The portion where the connection electrode pitch is wide is farther from the IDT electrode 3 than the portion where the connection electrode pitch is narrow. The reflector 13B also has the same configuration as that of the reflector 13A.

Here, as shown in FIG. 2, a dimension d of one period is twice the center-to-center distance in the second direction x between adjacent reflector electrode fingers 16. For example, in the connection electrode formation region C, a virtual line E is drawn for the dimension d of one period extending in the second direction x. In this case, on the virtual line E, there are a portion where the reflector connection electrode 15c is provided and a portion where the reflector connection electrode 15c is not provided. In other words, on the virtual line E, there are a portion where the piezoelectric substrate 2 is covered with a metal of the reflector 13A and a portion where the piezoelectric substrate 2 is not covered therewith. In this specification, a metallization ratio is the ratio of the portion where the piezoelectric substrate is covered with the metal constituting the reflector on the virtual line. More specifically, the metallization ratio is a value obtained by dividing the sum of the dimensions of the metal in the second direction x on the virtual line E by d.

For example, the metallization ratio of each portion in the connection electrode formation region C is large in the portion where the connection electrode pitch is narrow. On the other hand, the metallization ratio is small in the portion where the connection electrode pitch is wide.

The feature of this example embodiment is that the connection electrode formation region C of each reflector includes a portion with a different metallization ratio in the second direction x. Note that the connection electrode formation region C may include a portion with a different metallization ratio in the first direction y. This can prevent the energy of the acoustic wave from leaking to the side of each reflector busbar. This makes it possible to prevent an increase in return loss. Therefore, an increase in insertion loss is prevented in a case of using the acoustic wave device 1 in a filter device. This will be described in detail below by comparing this example embodiment with a comparative example.

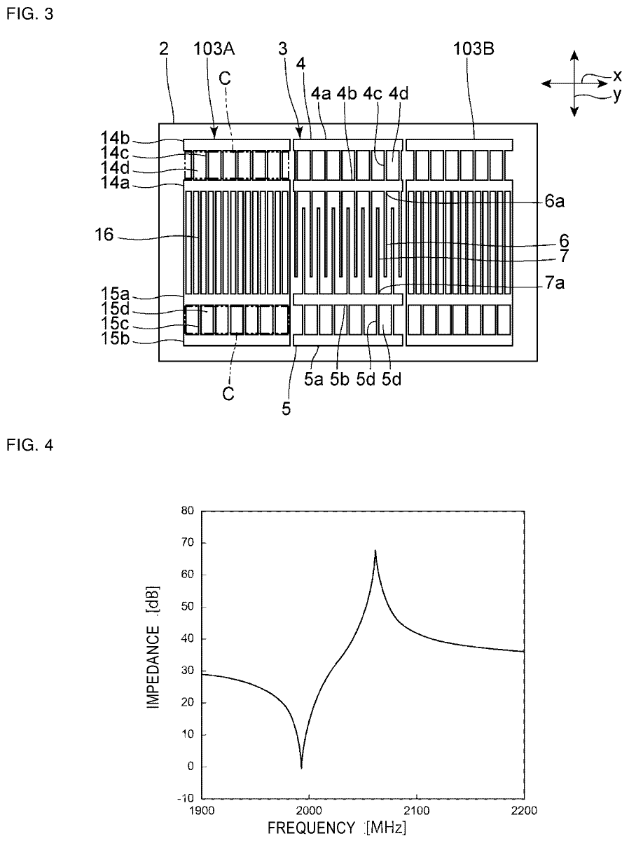

The comparative example differs from the first example embodiment in that, as shown in FIG. 3, every other reflector connection electrode is withdrawn across the entire connection electrode formation region C. Specifically, in the comparative example, the metallization ratio is constant in the connection electrode formation region C of a reflector 103A, for example. The same is true of the other reflector 103B.

The acoustic wave device 1 according to the first example embodiment is prepared so as to correspond to the configuration in which only the reflector connection electrode located second farthest from the IDT electrode 3 is withdrawn. An acoustic wave device, as another acoustic wave device 1 according to the first example embodiment, is also prepared so as to correspond to a configuration in which every other reflector connection electrode, that is, four reflector connection electrodes in total, including the reflector connection electrode located second farthest from the IDT electrode 3, are withdrawn. The return loss is compared between the acoustic wave device 1 according to the first example embodiment and the acoustic wave device of the comparative example. The results will be described below, along with impedance frequency characteristic of the acoustic wave device 1 according to the first example embodiment.

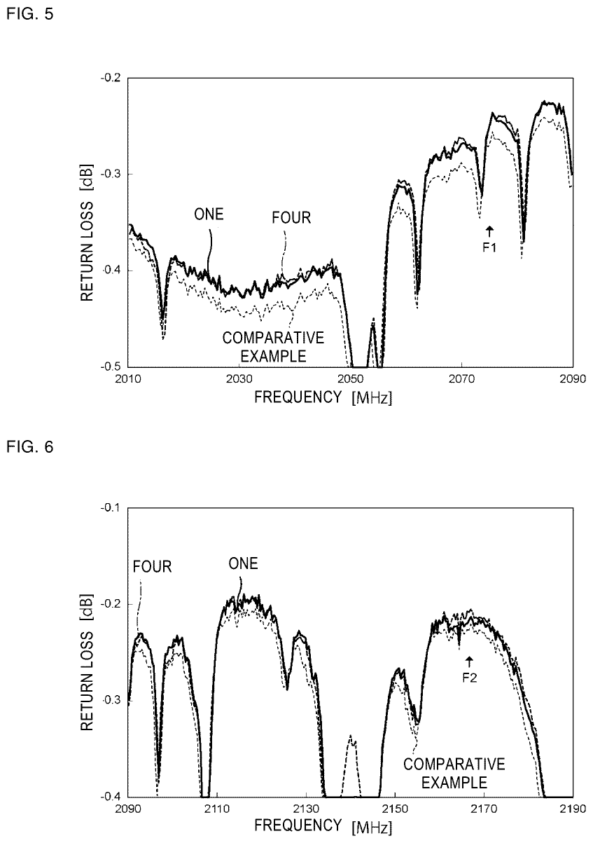

FIG. 4 is a graph showing the impedance frequency characteristics of the acoustic wave device according to the first example embodiment. FIG. 5 is a graph showing the return loss of the acoustic wave devices according to the first example embodiment and the comparative example. FIG. 6 is a graph showing the return loss of the acoustic wave devices according to the first example embodiment and the comparative example in a frequency range different from that of FIG. 5.

As shown in FIG. 4, an anti-resonant frequency of the acoustic wave device 1 of the first example embodiment is about 2061 MHz, for example. The upper end frequency of the stop band of the acoustic wave device 1 is about 2193 MHz, for example. The stop band is a region where the wavelength of the acoustic wave is constant due to the acoustic wave being confined in the metal grating of a periodic structure. The upper end of the stop band is a higher end portion of the stop band. The anti-resonant frequency and the upper end frequency of the stop band in the comparative example are almost the same as those in the first example embodiment.

As shown in FIGS. 5 and 6, it can be seen that the absolute value of the return loss is smaller in the first example embodiment than in the comparative example. In the first example embodiment, for example, the absolute value of the return loss is smaller in the frequency range equal to or higher than the frequency indicated by the arrow F1 in FIG. 5 and the frequency range equal to or lower than the frequency indicated by the arrow F2 in FIG. 6. Therefore, in the first example embodiment, the absolute value of the return loss is smaller in the range from the anti-resonant frequency to around the upper end of the stop band.

As shown in FIG. 2, the configuration of the first example embodiment corresponds to the configuration in which the reflector connection electrodes 15c on the side farther from the IDT electrode 3 are withdrawn. Therefore, the metallization ratio of the portion where the reflector connection electrodes 15c are withdrawn is smaller than the metallization ratio of the portion where no reflector connection electrodes are withdrawn. The difference in metallization ratio leads to a difference in degree of mass added by the metal constituting the reflector 13A. The portions of the reflector 13A with different degrees of mass added from each other are also different from each other in acoustic velocity.

In the second reflector busbar 15 of the reflector 13A according to the first example embodiment, the portions with different acoustic velocities are arranged in the second direction x. This makes it possible to reduce or prevent the leakage of acoustic waves from the reflector 13A, and to prevent an increase in return loss. In this specification, unless otherwise specified, preventing an increase in return loss means preventing an increase in the absolute value of the return loss.

As described above, the first reflector busbar 14 shown in FIG. 1 has the same configuration as that of the second reflector busbar 15. The reflector 13B has the same configuration as that of the reflector 13A. Therefore, the leakage of acoustic waves is reduced or prevented in each reflector busbar of each reflector. Therefore, in the case of using the acoustic wave device 1 in a filter device, an increase in insertion loss can be effectively prevented. For example, an increase in insertion loss can be effectively prevented near the end portion on the high frequency side of the pass band of the filter device.

At least one of the connection electrode formation regions C in the pair of reflector busbars of the pair of reflectors may include a portion with a different metallization ratio in at least one of the first direction y and the second direction x. This makes it possible to prevent an increase in return loss as described above. However, it is preferable that the connection electrode formation regions C in both reflector busbars of one reflector include a portion with a different metallization ratio in at least one of the first direction y and the second direction x. It is more preferable that all of the connection electrode formation regions C in both reflector busbars of both reflectors include a portion with a different metallization ratio in at least one of the first direction y and the second direction x. This makes it possible to effectively prevent an increase in return loss.

The relationship between the number of reflector connection electrodes, every other of which is withdrawn, and the Q value is obtained. Specifically, a plurality of acoustic wave devices are prepared, each having the configuration of the first example embodiment and having a different number of reflector connection electrodes, every other of which is withdrawn. The number of reflector connection electrodes, every other of which is withdrawn, is set to two, three, four, or eight. Note that the reflector busbars of each reflector in each acoustic wave device have the same configuration in which the reflector connection electrodes are withdrawn. The acoustic wave device of the comparative example shown in FIG. 3 is also prepared. The Q value of each of the acoustic wave devices thus prepared is measured. In each acoustic wave device, the number of pairs of electrode fingers of the IDT electrode is set to 100, and the number of pairs of reflector electrode fingers is set to 10. The measurement results of the comparative example will also be described below, in addition to the measurement result of each acoustic wave device having the configuration of the first example embodiment.

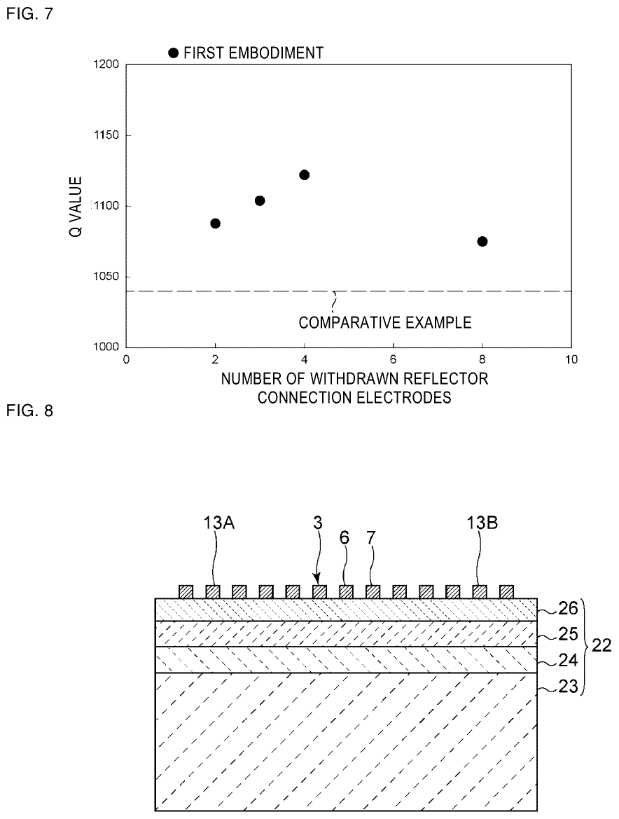

FIG. 7 is a graph showing the relationship between the number of reflector connection electrodes, every other of which is withdrawn, and the Q value in the acoustic wave device according to the first example embodiment. The dashed line in FIG. 7 indicates the result of the comparative example.

As shown in FIG. 7, it can be seen that the Q value is higher in the first example embodiment than in the comparative example. The Q value can thus be increased in the first example embodiment. Note that, in the first example embodiment, the Q value increases every time the number of withdrawn reflector connection electrodes increases to four. Specifically, the Q value increases every time the ratio of the number of withdrawn reflector connection electrodes to the number of reflector electrode fingers increases to about 20%, for example.

As described above, the piezoelectric substrate 2 of the acoustic wave device 1 shown in FIG. 1 is a substrate made only of a piezoelectric material. The piezoelectric substrate 2 may be a multilayer substrate including a piezoelectric layer. For example, in a modification of the first example embodiment shown in FIG. 8, a piezoelectric substrate 22 includes a support substrate 23, a high acoustic velocity film 24 as a high acoustic velocity material layer, a low acoustic velocity film 25, and a piezoelectric layer 26. The high acoustic velocity film 24 is provided on the support substrate 23. The low acoustic velocity film 25 is provided on the high acoustic velocity film 24. The piezoelectric layer 26 is provided on the low acoustic velocity film 25.

The low acoustic velocity film 25 is a film with a relatively low acoustic velocity. Specifically, the acoustic velocity of a bulk wave propagating through the low acoustic velocity film 25 is lower than that of a bulk wave propagating through the piezoelectric layer 26. The low acoustic velocity film 25 may be made of, for example, a dielectric such as glass, silicon oxide, silicon oxynitride, lithium oxide, tantalum oxide, or a compound of silicon oxide with fluorine, carbon, or boron added, or a material made of the above materials as a main component. In this specification, the term “main component” refers to a component that accounts for more than about 50 wt %, for example. The main component material may be in any of a single crystal state, a polycrystal state, and an amorphous state, or in a mixture thereof.

The high acoustic velocity material layer is a layer with a relatively high acoustic velocity. Specifically, the acoustic velocity of a bulk wave propagating through the high acoustic velocity material layer is higher than that of the acoustic wave propagating through the piezoelectric layer 26. In this modification, the high acoustic velocity material layer is the high acoustic velocity film 24. Examples of the high acoustic velocity material include a piezoelectric material such as aluminum nitride, lithium tantalate, lithium niobate, or crystal, a ceramic such as alumina, sapphire, magnesia, silicon nitride, silicon carbide, zirconia, cordierite, mullite, steatite, forsterite, spinel, or sialon, a dielectric such as aluminum oxide, silicon oxynitride, DLC (diamond-like carbon), or diamond, and a semiconductor such as silicon, or a material made of the above materials as a main component. The spinel includes an aluminum compound including one or more elements selected from Mg, Fe, Zn, or Mn, and the like, and oxygen. Examples of the spinel include MgAl₂O₄, FeAl₂O₄, ZnAl₂O₄, or MnAl₂O₄.

Examples of the material of the support substrate 23 include a piezoelectric material such as aluminum nitride, lithium tantalate, lithium niobate, or crystal, a ceramic such as alumina, sapphire, magnesia, silicon nitride, silicon carbide, zirconia, cordierite, mullite, steatite, or forsterite, a dielectric such as diamond or glass, a semiconductor such as silicon or gallium nitride, and a resin, or a material made of the above materials as a main component.

In the piezoelectric substrate 22 of this modification, the high acoustic velocity film 24 as the high acoustic velocity material layer, the low acoustic velocity film 25, and the piezoelectric layer 26 are laminated in this order. This makes it possible to effectively confine the energy of the acoustic waves to the piezoelectric layer 26 side. In addition, an increase in return loss can also be prevented in this modification, as in the first example embodiment.

The multilayer structure of the piezoelectric substrate is not limited to the above. For example, the piezoelectric substrate may be a multilayer substrate of a support substrate, a high acoustic velocity film, and a piezoelectric layer. The high acoustic velocity material layer may be a high acoustic velocity support substrate. In this case, the piezoelectric substrate may be a multilayer substrate of a high acoustic velocity support substrate, a low acoustic velocity film, and a piezoelectric layer, or a multilayer substrate of a high acoustic velocity support substrate and a piezoelectric layer. It is possible also in such cases to effectively confine the energy of the acoustic waves to the piezoelectric layer side. In addition, an increase in return loss can also be prevented, as in the modification of the first example embodiment.

Hereinafter, second to ninth example embodiments will be described, which are different from the first example embodiment only in the configuration of the reflector busbar. In each of the example embodiments other than the first example embodiment, the reflector busbar includes a portion with a different metallization ratio. In each of the following example embodiments, each reflector busbar of each reflector has the same configuration. Therefore, the configuration of a second reflector busbar of one of the reflectors in each example embodiment will be described below. It is possible also in each of the example embodiments other than the first example embodiment to prevent an increase in return loss. Therefore, an increase in insertion loss is prevented also in a case of using an acoustic wave device of each example embodiment in a filter device. In the acoustic wave device according to each of the following example embodiments, the anti-resonant frequency and the upper end frequency of the stop band are almost the same as those in the first example embodiment.

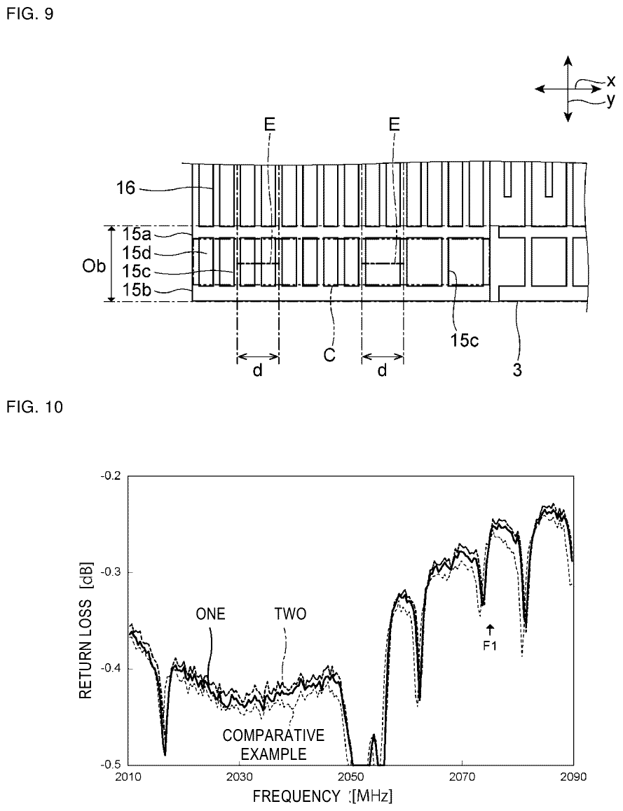

FIG. 9 is a plan view showing the vicinity of a second reflector busbar of a reflector according to the second example embodiment.

The second example embodiment differs from the first example embodiment in that the portion of the connection electrode formation region C where the connection electrode pitch is wide is closer to the IDT electrode 3 than the portion where the connection electrode pitch is narrow. In the second example embodiment, the portion of the connection electrode formation region C where the metallization ratio is small is closer to the IDT electrode 3 than the portion where the metallization ratio is large.

A comparison of the return loss between the second example embodiment and the comparative example shown in FIG. 3 will be described below. An acoustic wave device according to the second example embodiment is prepared so as to correspond to a configuration in which only the reflector connection electrode 15c located second closest to the IDT electrode 3 is withdrawn. Another acoustic wave device according to the second example embodiment is also prepared so as to correspond to a configuration in which every other reflector connection electrode 15c, that is, two reflector connection electrodes 15c in total, including the reflector connection electrode 15c located second closest to the IDT electrode 3, are withdrawn. The return loss is compared between the acoustic wave device according to the second example embodiment and the acoustic wave device of the comparative example.

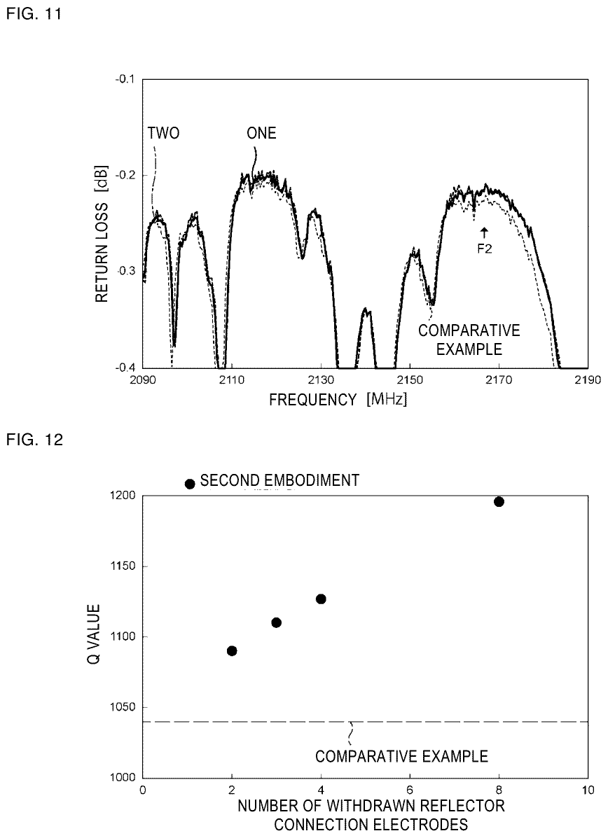

FIG. 10 is a graph showing the return loss of the acoustic wave devices according to the second example embodiment and the comparative example. FIG. 11 is a graph showing the return loss of the acoustic wave devices according to the second example embodiment and the comparative example in a frequency range different from that of FIG. 10.

As shown in FIGS. 10 and 11, the absolute value of the return loss is smaller in the second example embodiment than in the comparative example. For example, in the second example embodiment, the absolute value of the return loss is smaller in the frequency range equal to or higher than the frequency indicated by the arrow F1 in FIG. 10 and in the frequency range equal to or lower than the frequency indicated by the arrow F2 in FIG. 11. Therefore, in the second example embodiment, the absolute value of the return loss is smaller in the range from the anti-resonant frequency to around the upper end of the stop band.

The relationship between the number of the reflector connection electrodes 15c, every other of which is withdrawn, and the Q value is obtained. Specifically, a plurality of acoustic wave devices are prepared, each having the configuration of the second example embodiment and having a different number of the reflector connection electrodes 15c, every other of which is withdrawn. The number of the reflector connection electrodes 15c, every other of which is withdrawn, is set to two, three, four, or eight. Note that the reflector busbars of each reflector in each acoustic wave device have the same configuration in which the reflector connection electrodes are withdrawn. The acoustic wave device of the comparative example shown in FIG. 3 is also prepared. The Q value of each of the acoustic wave devices thus prepared is measured. In each acoustic wave device, the number of pairs of electrode fingers of the IDT electrode 3 is set to 100, and the number of pairs of the reflector electrode fingers 16 is set to 10. The measurement results of the comparative example will also be described below, in addition to the measurement result of each acoustic wave device having the configuration of the second example embodiment.

FIG. 12 is a graph showing the relationship between the number of reflector connection electrodes, every other of which is withdrawn, and the Q value in the acoustic wave device according to the second example embodiment. The dashed line in FIG. 12 indicates the result of the comparative example.

As shown in FIG. 12, it can be seen that the Q value is higher in the second example embodiment than in the comparative example. The Q value can thus be increased in the second example embodiment. It can be seen that, in the second example embodiment, the Q value increases every time the number of withdrawn reflector connection electrodes 15c increases to eight. Specifically, the Q value increases every time the ratio of the number of withdrawn reflector connection electrodes 15c to the number of reflector electrode fingers 16 increases to 40%.

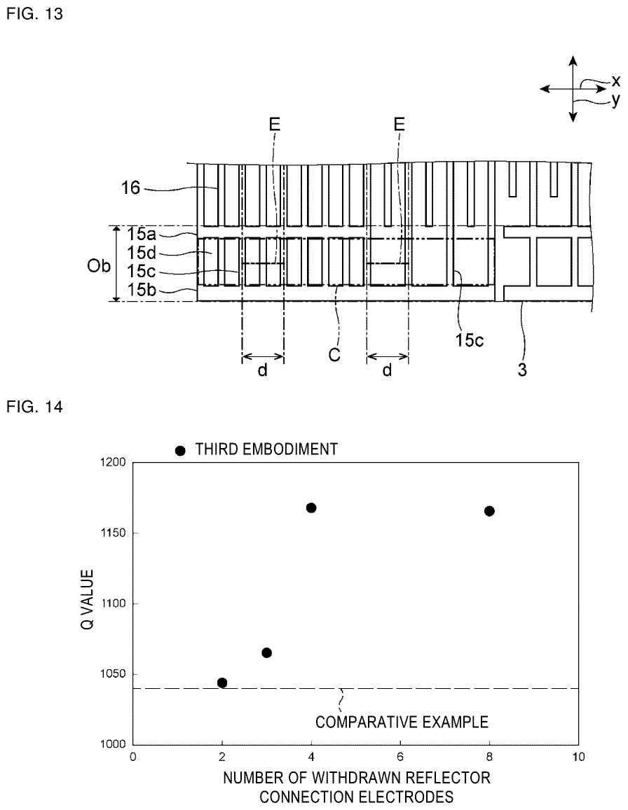

FIG. 13 is a plan view showing the vicinity of a second reflector busbar of a reflector according to the third example embodiment.

The third example embodiment differs from the second example embodiment in that only some of all the reflector electrode fingers 16 are connected to the inner reflector busbar portion 15a. Some of the reflector electrode fingers 16 are indirectly connected to the respective reflector connection electrodes 15c through the inner reflector busbar portion 15a. Specifically, the reflector connection electrodes 15c are provided on the extension lines of all the reflector electrode fingers 16 connected to the inner reflector busbar portion 15a. On the other hand, the reflector connection electrodes 15c are directly connected to the leading ends of some of the plurality of reflector electrode fingers 16 that are not connected to the inner reflector busbar portion 15a. On the other hand, the leading ends of other reflector electrode fingers 16 among the plurality of reflector electrode fingers 16 that are not connected to the inner reflector busbar portion 15a face the outer reflector busbar portion 15b across a gap.

The configuration of the third example embodiment corresponds to a configuration in which the reflector connection electrodes 15c are withdrawn in the portion where the reflector electrode fingers 16 are not connected to either the inner reflector busbar portion 15a or the reflector connection electrodes 15c. The connection electrode pitch is wider in this portion. In the third example embodiment, as in the second example embodiment, the portion of the connection electrode formation region C where the connection electrode pitch is wide is closer to the IDT electrode 3 than the portion where the connection electrode pitch is narrow. Therefore, in the connection electrode formation region C, the portion with a smaller metallization ratio is closer to the IDT electrode 3 than the portion with a larger metallization ratio.

As in the first example embodiment, however, in the connection electrode formation region C, the portion with a smaller metallization ratio may be farther from the IDT electrode 3 than the portion with a larger metallization ratio. In this case, the portion where the plurality of reflector electrode fingers 16 are not connected to the inner reflector busbar portion 15a may be farther from the IDT electrode 3 than the portion where the plurality of reflector electrode fingers 16 are connected to the inner reflector busbar portion 15a.

Here, the relationship between the number of the reflector connection electrodes 15c, every other of which is withdrawn, and the Q value is obtained. Specifically, a plurality of acoustic wave devices are prepared, each having the configuration of the third example embodiment and having a different number of the reflector connection electrodes 15c, every other of which is withdrawn. The number of the reflector connection electrodes 15c, every other of which is withdrawn, is set to two, three, four, or eight, for example. Note that the reflector busbars of each reflector in each acoustic wave device have the same configuration in which the reflector connection electrodes are withdrawn. The acoustic wave device of the comparative example shown in FIG. 3 is also prepared. The Q value of each of the acoustic wave devices thus prepared is measured. In each acoustic wave device, the number of pairs of electrode fingers of the IDT electrode 3 is set to 100, and the number of pairs of the reflector electrode fingers 16 is set to 10, for example. The measurement results of the comparative example will also be described below, in addition to the measurement result of each acoustic wave device having the configuration of the third example embodiment.

FIG. 14 is a graph showing the relationship between the number of reflector connection electrodes, every other of which is withdrawn, and the Q value in the acoustic wave device according to the third example embodiment. The dashed line in FIG. 14 indicates the result of the comparative example.

As shown in FIG. 14, it can be seen that the Q value is higher in the third example embodiment than in the comparative example. The Q value can thus be increased in the third example embodiment. It can be seen that, in the third example embodiment, the Q value increases every time the number of withdrawn reflector connection electrodes 15c increases to four. It can also be seen that there is almost no change in Q when the number of withdrawn reflector connection electrodes 15c is equal to or more than four. Specifically, the Q value increases every time the ratio of the number of withdrawn reflector connection electrodes 15c to the number of reflector electrode fingers 16 increases to 20%.

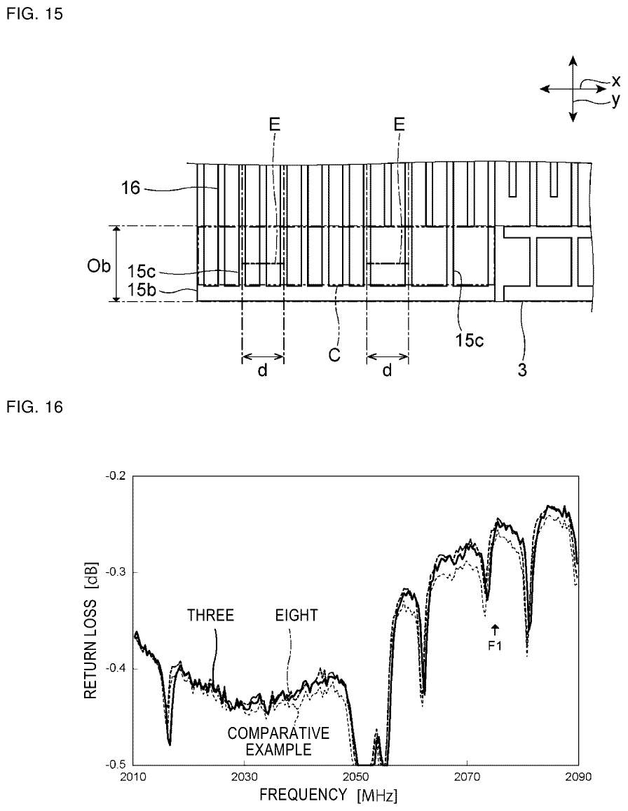

FIG. 15 is a plan view showing the vicinity of a second reflector busbar of a reflector according to the fourth example embodiment.

The fourth example embodiment differs from the second example embodiment in that the reflector busbar has no inner reflector busbar portion. Therefore, some of all the reflector electrode fingers 16 are directly connected to the reflector connection electrodes 15c.

A comparison of return loss between the fourth example embodiment and the comparative example shown in FIG. 3 will be described below. An acoustic wave device according to the fourth example embodiment is prepared so as to correspond to a configuration in which every other reflector connection electrode 15c, that is, three reflector connection electrodes 15c in total, including the reflector connection electrode 15c located second closest to the IDT electrode 3, are withdrawn. Another acoustic wave device according to the fourth example embodiment is also prepared so as to correspond to a configuration in which every other reflector connection electrode 15c, that is, eight reflector connection electrodes 15c in total, including the reflector connection electrode 15c located second closest to the IDT electrode 3, are withdrawn. The return loss is compared between these acoustic wave devices according to the fourth example embodiment and the acoustic wave device of the comparative example.

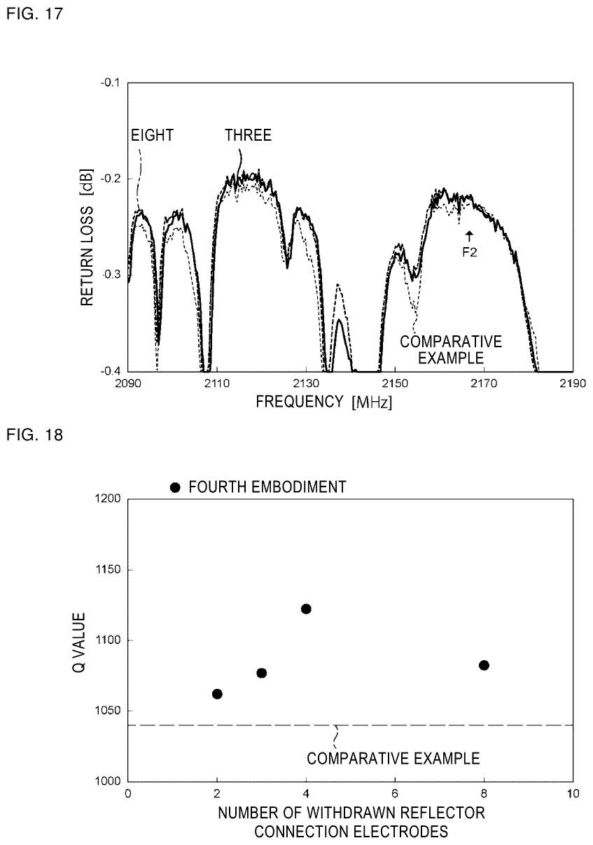

FIG. 16 is a graph showing the return loss of the acoustic wave devices according to the fourth example embodiment and the comparative example. FIG. 17 is a graph showing the return loss of the acoustic wave devices according to the fourth example embodiment and the comparative example in a frequency range different from that of FIG. 16.

As shown in FIGS. 16 and 17, the absolute value of the return loss is smaller in the fourth example embodiment than in the comparative example. For example, in the fourth example embodiment, the absolute value of the return loss is smaller in the frequency range equal to or higher than the frequency indicated by the arrow F1 in FIG. 16 and in the frequency range equal to or lower than the frequency indicated by the arrow F2 in FIG. 17. Therefore, in the fourth example embodiment, the absolute value of the return loss is smaller in the range from the anti-resonant frequency to around the upper end of the stop band.

The relationship between the number of the reflector connection electrodes 15c, every other of which is withdrawn, and the Q value is also obtained. Specifically, a plurality of acoustic wave devices are prepared, each having the configuration of the fourth example embodiment and having a different number of the reflector connection electrodes 15c, every other of which is withdrawn. The number of the reflector connection electrodes 15c, every other of which is withdrawn, is set to two, three, four, or eight. Note that the reflector busbars of each reflector in each acoustic wave device have the same configuration in which the reflector connection electrodes are withdrawn. The acoustic wave device of the comparative example shown in FIG. 3 is also prepared. The Q value of each of the acoustic wave devices thus prepared is measured. In each acoustic wave device, the number of pairs of electrode fingers of the IDT electrode 3 is set to 100, and the number of pairs of the reflector electrode fingers 16 is set to 10, for example. The measurement results of the comparative example will also be described below, in addition to the measurement result of each acoustic wave device having the configuration of the fourth example embodiment.

FIG. 18 is a graph showing the relationship between the number of reflector connection electrodes, every other of which is withdrawn, and the Q value in the acoustic wave device according to the fourth example embodiment. The dashed line in FIG. 18 indicates the result of the comparative example.

As shown in FIG. 18, it can be seen that the Q value is higher in the fourth example embodiment than in the comparative example. The Q value can thus be increased in the fourth example embodiment. It can be seen that, in the fourth example embodiment, the Q value increases every time the number of withdrawn reflector connection electrodes 15c increases to four. Specifically, the Q value increases every time the ratio of the number of withdrawn reflector connection electrodes 15c to the number of reflector electrode fingers 16 increases to 20%.

In the first to fourth example embodiments, the description is given of the example where the portion with a wide connection electrode pitch and the portion with a narrow connection electrode pitch are provided in the connection electrode formation region C. However, the positional relationship between these portions is not particularly limited. The connection electrode pitch in a portion of the connection electrode formation region C may be wider than the other connection electrode pitch. This makes it possible to prevent an increase in return loss.

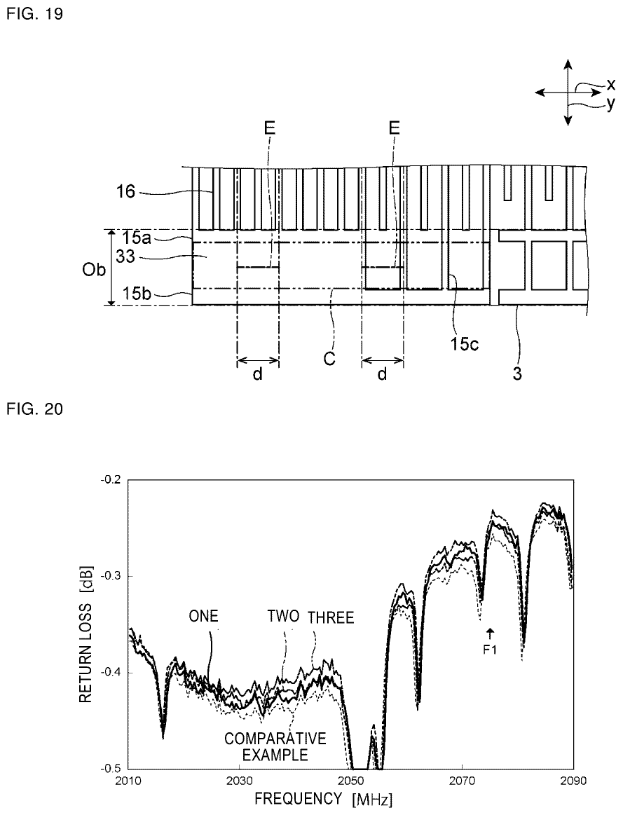

FIG. 19 is a plan view showing the vicinity of a second reflector busbar of a reflector according to the fifth example embodiment.

The fifth example embodiment differs from the third example embodiment in that the inner reflector busbar portion 15a and the outer reflector busbar portion 15b are connected by a metal film 33 in a portion of the connection electrode formation region C. The dimension of the metal film 33 in the second direction x is larger than the dimension d of one period described above. Therefore, the metallization ratio is 1 in the portion where the metal film 33 is provided. On the other hand, the metallization ratio is less than 1 in the portion of the connection electrode formation region C where the metal film 33 is not provided.

The inner reflector busbar portion 15a is not provided in the portion of the second reflector busbar where the metal film 33 is not provided. This portion has the same configuration as that of the portion where the inner reflector busbar portion 15a is not provided in the third example embodiment. More specifically, a plurality of reflector connection electrodes 15c are provided in the portion of the connection electrode formation region C where the metal film 33 is not provided. The plurality of reflector connection electrodes 15c are each directly connected to the reflector electrode fingers 16.

In the fifth example embodiment, the configuration of the portion of the connection electrode formation region C where the metal film 33 is not provided corresponds to a configuration in which every other reflector connection electrode 15c is withdrawn. More specifically, as shown in FIG. 19, the configuration of the portion where the metal film 33 is not provided corresponds to a configuration in which every other reflector connection electrode 15c is withdrawn, that is, three reflector connection electrodes 15c in total are withdrawn. In this case, the number of the reflector electrode fingers 16 that do not overlap the metal film 33 in the first direction y is six. Specifically, in the fifth example embodiment, the number of the reflector electrode fingers 16 that do not overlap the metal film 33 in the first direction y is twice the number of the withdrawn reflector connection electrodes 15c.

The configuration of the portion where the metal film 33 is not provided does not have to correspond to the configuration in which every other reflector connection electrode 15c is withdrawn. For example, all of the reflector electrode fingers 16 provided in the portion that does not overlap the metal film 33 in the first direction y may be directly connected to the reflector connection electrodes 15c.

As shown in FIG. 19, all of the portions of the inner reflector busbar portion 15a in the second direction x are connected to the metal film 33. However, the inner reflector busbar portion 15a may also be provided in the portion of the second reflector busbar where the metal film 33 is not provided. For example, the portion of the second reflector busbar where the metal film 33 is not provided may have the same configuration as that of the portion with a small metallization ratio or the portion with a large metallization ratio in the second example embodiment shown in FIG. 9. In such cases, again, in the connection electrode formation region C, the metallization ratio of the portion where the metal film 33 is provided is larger than the metallization ratio of the portion where the metal film 33 is not provided.

In the connection electrode formation region C, the portion where the metal film 33 is provided is farther from the IDT electrode 3 in the second direction x than the portion where the metal film 33 is not provided. More specifically, the metal film 33 overlaps a plurality of reflector electrode fingers 16, including the reflector electrode finger 16 farthest from the IDT electrode 3, in the first direction y. More specifically, the metal film 33 overlaps three or more reflector electrode fingers 16, including the reflector electrode finger 16 farthest from the IDT electrode 3, in the first direction y. However, the portion where the metal film 33 is provided may be closer to the IDT electrode 3 in the second direction x than the portion where the metal film 33 is not provided. In this case, the metal film 33 may overlap the plurality of reflector electrode fingers 16, including the reflector electrode finger 16 closest to the IDT electrode 3, in the first direction y.

A comparison of return loss between the fifth example embodiment and the comparative example shown in FIG. 3 will be described below. An acoustic wave device according to the fifth example embodiment is prepared so as to correspond to a configuration in which only the reflector connection electrode 15c located second closest to the IDT electrode 3 is withdrawn. Another acoustic wave device according to the fifth example embodiment is also prepared so as to correspond to a configuration in which every other reflector connection electrode 15c, that is, two reflector connection electrodes 15c in total, including the reflector connection electrode 15c located second closest to the IDT electrode 3, are withdrawn. Still another acoustic wave device according to the fifth example embodiment is also prepared so as to correspond to a configuration in which every other reflector connection electrode 15c, that is, three reflector connection electrodes 15c in total, including the reflector connection electrode 15c located second closest to the IDT electrode 3, are withdrawn. Specifically, in each of the fifth acoustic wave devices, the number of the reflector electrode fingers 16 that do not overlap the metal film 33 in the first direction y is two, four, or six. The return loss is compared between these acoustic wave devices according to the fifth example embodiment and the acoustic wave device of the comparative example.

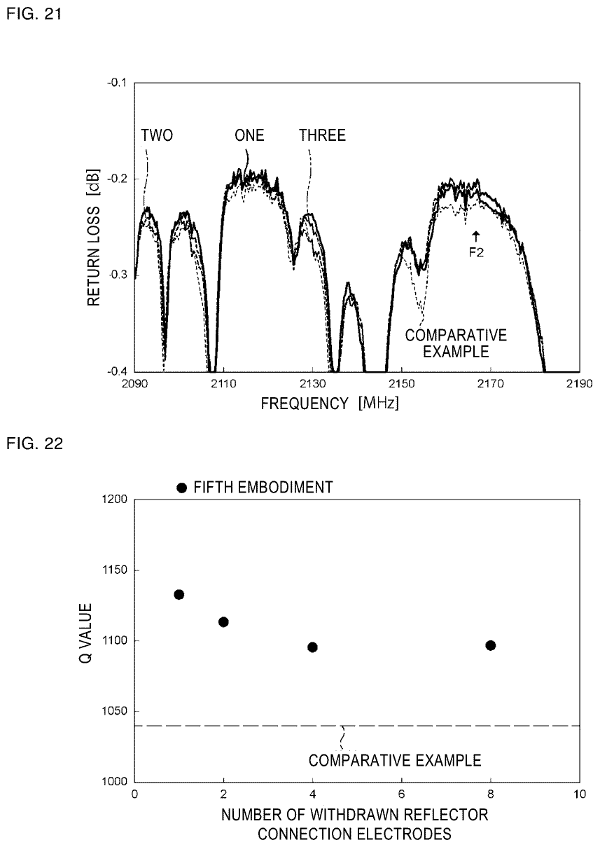

FIG. 20 is a graph showing the return loss of the acoustic wave devices according to the fifth example embodiment and the comparative example. FIG. 21 is a graph showing the return loss of the acoustic wave devices according to the fifth example embodiment and the comparative example in a frequency range different from that of FIG. 20. Note that the numbers of reflector connection electrodes shown in FIGS. 20 and 21 each correspond to the number of the withdrawn reflector connection electrodes 15c, as in FIG. 10 and the like.

As shown in FIGS. 20 and 21, the absolute value of the return loss is smaller in the fifth example embodiment than in the comparative example. For example, in the fifth example embodiment, the absolute value of the return loss is smaller in the frequency range equal to or higher than the frequency indicated by the arrow F1 in FIG. 20 and in the frequency range equal to or lower than the frequency indicated by the arrow F2 in FIG. 21. Therefore, in the fifth example embodiment, the absolute value of the return loss is smaller in the range from the anti-resonant frequency to around the upper end of the stop band.

The relationship between the number of the reflector connection electrodes 15c, every other of which is withdrawn, and the Q value is also obtained. Specifically, a plurality of acoustic wave devices are prepared, each having the configuration of the fifth example embodiment and having a different number of the reflector connection electrodes 15c, every other of which is withdrawn. In other words, a plurality of acoustic wave devices are prepared, each having a different number of reflector electrode fingers 16 that did not overlap the metal film 33 in the first direction y. Note that the number of the reflector connection electrodes 15c, every other of which is withdrawn, is set to one, two, four, or eight, for example. Specifically, the number of the reflector electrode fingers 16 that do not overlap the metal film 33 in the first direction y is set to two, four, eight, or sixteen, for example. Note that the reflector busbars of each reflector in each acoustic wave device have the same configuration in which the reflector connection electrodes are withdrawn and the metal film is provided.

The acoustic wave device of the comparative example shown in FIG. 3 is also prepared. The Q value is measured for each of the acoustic wave devices according to the fifth example embodiment thus prepared and the acoustic wave device of the comparative example. In each acoustic wave device, the number of pairs of electrode fingers of the IDT electrode 3 is set to 100, and the number of pairs of the reflector electrode fingers 16 is set to 10. The measurement results of the comparative example will also be described below, in addition to the measurement result of each acoustic wave device having the configuration of the fifth example embodiment.

FIG. 22 is a graph showing the relationship between the number of reflector connection electrodes, every other of which is withdrawn, and the Q value in the acoustic wave device according to the fifth example embodiment. The dashed line in FIG. 22 indicates the result of the comparative example.

As shown in FIG. 22, it can be seen that the Q value is higher in the fifth example embodiment than in the comparative example. The Q value can thus be increased in the fifth example embodiment. It can be seen that the Q value is particularly high in the fifth example embodiment when only one reflector connection electrode 15c is withdrawn. Specifically, the Q value is particularly high when the ratio of the number of the withdrawn reflector connection electrodes 15c to the number of the reflector electrode fingers 16 is 5%. In other words, the Q value is particularly high when the number of the reflector electrode fingers 16 that do not overlap the metal film 33 in the first direction y is two and the ratio of the number of these reflector electrode fingers 16 to the total number of the reflector electrode fingers 16 is 10%.

In the first to fifth example embodiments, the description is given of the example where the connection electrode formation region C of the reflector includes portions with different metallization ratios in the second direction x. Note that the connection electrode formation region C of the reflector may include portions with different metallization ratios in the first direction y. This example will be described in the sixth to ninth example embodiments. In the sixth to ninth example embodiments, it is possible to prevent an increase in return loss, as in the first example embodiment. Therefore, an increase in insertion loss is prevented also in a case of using the acoustic wave device of each example embodiment in a filter device.

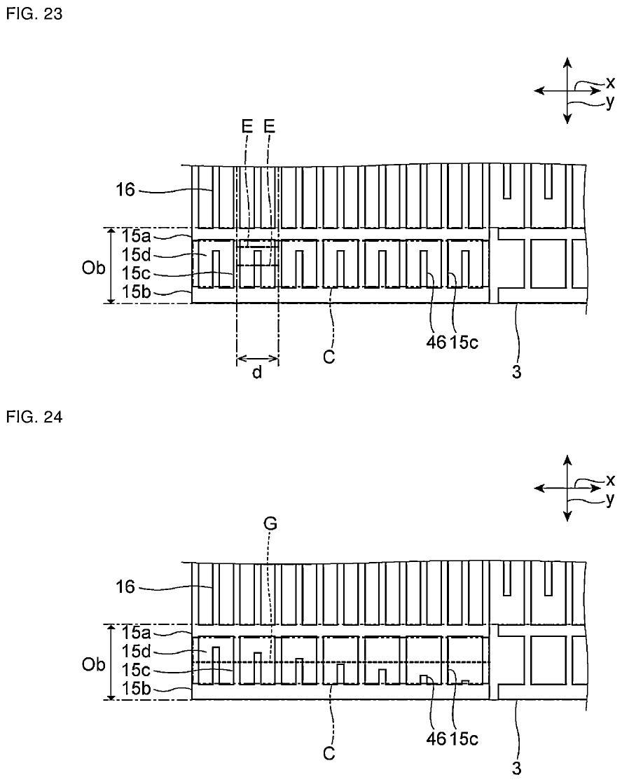

FIG. 23 is a plan view showing the vicinity of a second reflector busbar of a reflector according to the sixth example embodiment.

In the sixth example embodiment, as in the first example embodiment, the reflector busbar includes an inner reflector busbar portion 15a and an outer reflector busbar portion 15b. All of the reflector electrode fingers 16 are connected to the inner reflector busbar portion 15a. Therefore, the plurality of reflector electrode fingers 16 are indirectly connected to the plurality of reflector connection electrodes 15c through the inner reflector busbar portion 15a. The sixth example embodiment differs from the first example embodiment in that the configuration of the connection electrode formation region C corresponds to a configuration in which every other reflector electrode finger 16 is withdrawn across the entire region. The sixth example embodiment also differs from the first example embodiment in that the reflector busbar includes a plurality of dummy electrode fingers 46.

More specifically, the dummy electrode fingers 46 extend in the first direction y. The plurality of dummy electrode fingers 46 are positioned between the respective plurality of reflector connection electrodes 15c. The plurality of dummy electrode fingers 46 each include one end connected to the outer reflector busbar portion 15b. The plurality of dummy electrode fingers 46 each include the other end facing the inner reflector busbar portion 15a across a gap. In the sixth example embodiment, the plurality of dummy electrode fingers 46 all have the same length. The length of the dummy electrode finger 46 is the dimension of the dummy electrode finger 46 in the first direction y.

In the sixth example embodiment, the reflector electrode finger 16 is located on the extension line of each dummy electrode finger 46. However, the reflector electrode finger 16 does not necessarily have to be located on the extension line of the dummy electrode finger 46.

In the connection electrode formation region C according to the sixth example embodiment, the metallization ratio is constant in the second direction x. Specifically, in the portion where the dummy electrode fingers 46 are provided, for example, the dummy electrode fingers 46 and the reflector connection electrodes 15c are arranged at even intervals in the second direction x. On the other hand, in the portion between the dummy electrode fingers 46 and the inner reflector busbar portion 15a, the reflector connection electrodes 15c are arranged at even intervals in the second direction x. However, the metallization ratio in the portion where the dummy electrode fingers 46 are provided is different from the metallization ratio in the portion between the dummy electrode fingers 46 and the inner reflector busbar portion 15a. More specifically, the metallization ratio in the portion where the dummy electrode fingers 46 are provided is larger than the metallization ratio in the portion between the dummy electrode fingers 46 and the inner reflector busbar portion 15a. In the sixth example embodiment, the connection electrode formation region C thus includes the portions with different metallization ratios in the first direction y.

As described above, the difference in metallization ratio leads to a difference in degree of mass added by the metal constituting the reflector. The portions of the reflector with different degrees of mass added from each other are also different from each other in acoustic velocity. In the reflector busbar according to the sixth example embodiment, the portions with different acoustic velocities are arranged in the first direction y. This makes it possible to reduce or prevent the leakage of acoustic waves from the reflector, and to prevent an increase in return loss. Therefore, an increase in insertion loss is prevented in a case of using the acoustic wave device in a filter device.

The length of at least one of the plurality of dummy electrode fingers 46 may be different from the length of the other dummy electrode fingers 46.

FIG. 24 is a plan view showing the vicinity of a second reflector busbar of a reflector according to the seventh example embodiment.

The seventh example embodiment differs from the sixth example embodiment in that the plurality of dummy electrode fingers 46 do not have the same length. More specifically, the dummy electrode fingers 46 provided at positions farther from the IDT electrode 3 in the second direction x have a longer length. Therefore, on the virtual line G in FIG. 24, for example, a portion where the dummy electrode fingers 46 are provided between adjacent reflector connection electrodes 15c and a portion where the dummy electrode fingers 46 are not provided are included. More specifically, the virtual line G is a virtual line extending across the entire connection electrode formation region C in the second direction x. There are an infinite number of such virtual lines, and FIG. 24 shows one example. The connection electrode formation region C in the seventh example embodiment includes, on the virtual line G, a portion where the dummy electrode fingers 46 are provided between adjacent reflector connection electrodes 15c and a portion where the dummy electrode fingers 46 are not provided. Therefore, the connection electrode formation region C includes portions with different metallization ratios in both the first direction y and the second direction x.

Note that the dummy electrode fingers 46 provided closer to the IDT electrode 3 in the second direction x may have a longer length.

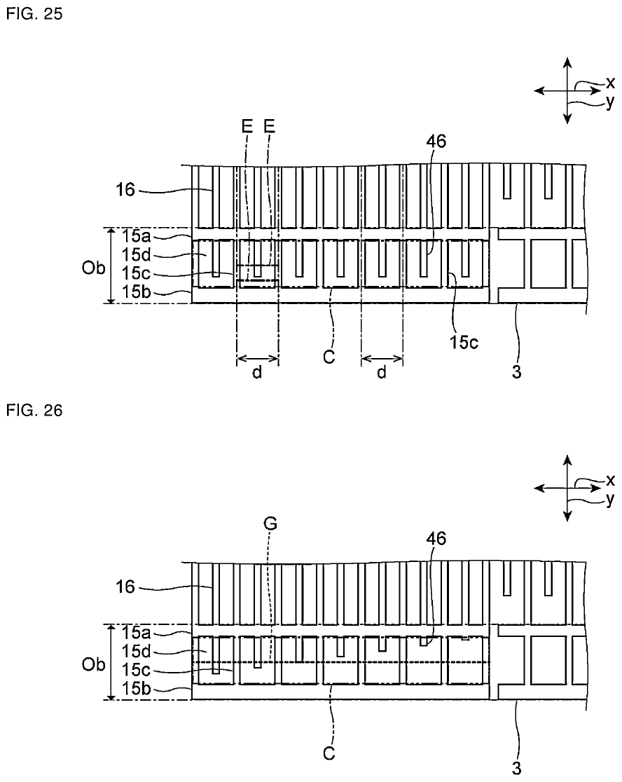

FIG. 25 is a plan view showing the vicinity of a second reflector busbar of a reflector according to the eighth example embodiment.

The eighth example embodiment differs from the sixth example embodiment in that the plurality of dummy electrode fingers 46 each include one end connected to the inner reflector busbar portion 15a. The eighth example embodiment also differs from the sixth example embodiment in that the plurality of dummy electrode fingers 46 each include the other end facing the outer reflector busbar portion 15b across a gap. In the eighth example embodiment, the plurality of dummy electrode fingers 46 all have the same length.

Even when the plurality of dummy electrode fingers 46 each include one end connected to the inner reflector busbar portion 15a, the length of at least one of the plurality of dummy electrode fingers 46 may be different from the length of the other dummy electrode fingers 46.

FIG. 26 is a plan view showing the vicinity of a second reflector busbar of a reflector according to the ninth example embodiment.

The ninth example embodiment differs from the eighth example embodiment in that the plurality of dummy electrode fingers 46 do not have the same length. More specifically, the dummy electrode fingers 46 provided at positions farther from the IDT electrode 3 in the second direction x have a longer length. As in the seventh example embodiment, the connection electrode formation region C in the ninth example embodiment includes, on the virtual line G, a portion where the dummy electrode fingers 46 are provided and a portion where the dummy electrode fingers 46 are not provided. Thus, the connection electrode formation region C includes portions with different metallization ratios in both the first direction y and the second direction x.

In the second direction x, the dummy electrode fingers 46 closer to the IDT electrode 3 may have a longer length.

A comparison of the return loss between the sixth to ninth example embodiments and the comparative example shown in FIG. 3 will be described below.

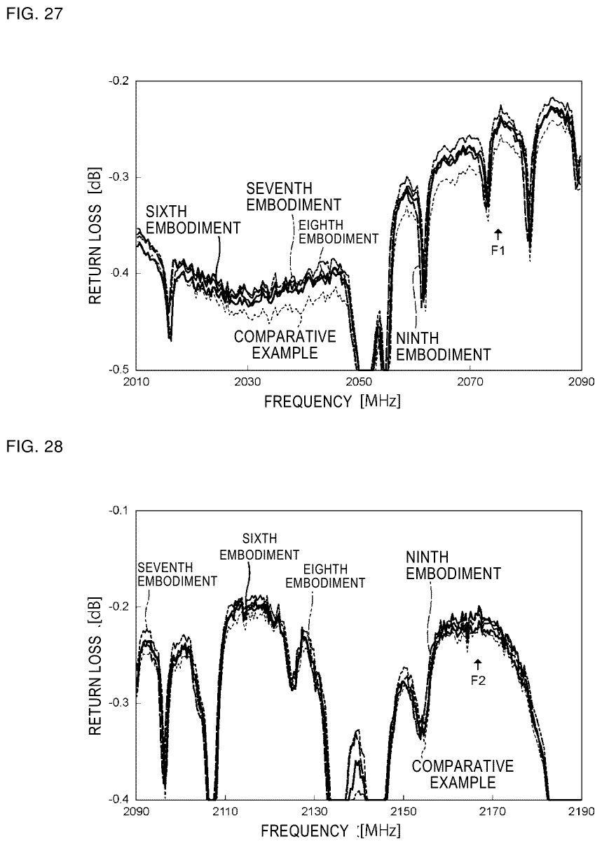

FIG. 27 is a graph showing the return loss of the acoustic wave devices according to the sixth to ninth example embodiments and the comparative example. FIG. 28 is a graph showing the return loss of the acoustic wave devices according to the sixth to ninth example embodiments and the comparative example in a frequency range different from that of FIG. 27.

As shown in FIGS. 27 and 28, the absolute value of the return loss is smaller in all of the sixth to ninth example embodiments than in the comparative example. For example, in the sixth to ninth example embodiments, the absolute value of the return loss is small in the frequency range equal to or higher than the frequency indicated by the arrow F1 in FIG. 27 and in the frequency range equal to or lower than the frequency indicated by the arrow F2 in FIG. 28. Therefore, in the sixth to ninth example embodiments, the absolute value of the return loss is small in the range from the anti-resonant frequency to around the upper end of the stop band. An increase in return loss can thus be prevented in the sixth to ninth example embodiments.

The configurations of the first to ninth example embodiments can be suitably used in an acoustic wave device that uses a piston mode. This example will be described below.

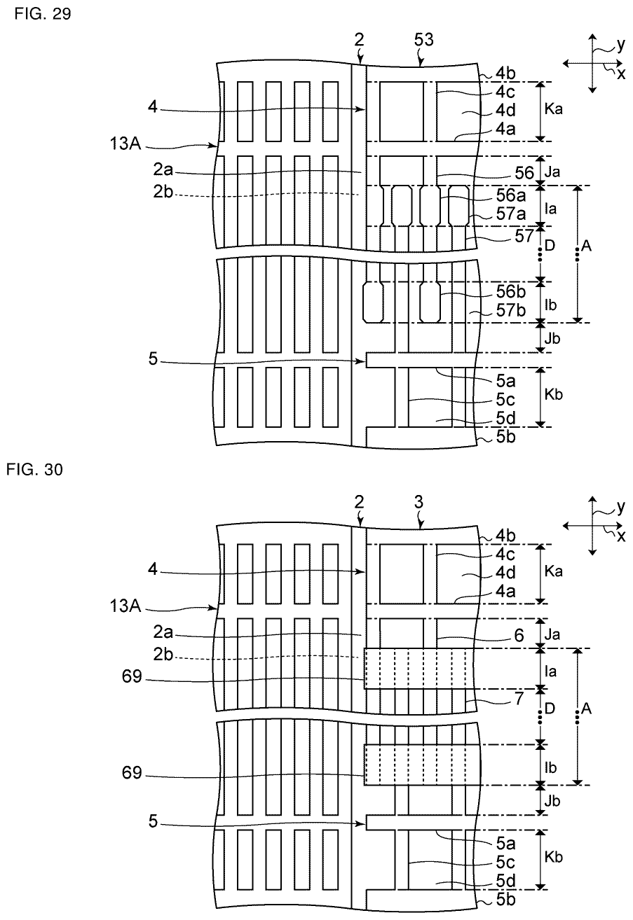

FIG. 29 is a partially enlarged schematic plan view showing the vicinity of a first busbar and a second busbar in an IDT electrode according to a tenth example embodiment.

This example embodiment differs from the first example embodiment in a configuration of an IDT electrode 53. Otherwise, the acoustic wave device of this example embodiment has the same configuration as that of the acoustic wave device 1 of the first example embodiment.

An intersection region A of the IDT electrode 53 includes a central region D and a pair of edge regions. Specifically, the pair of edge regions include a first edge region Ia and a second edge region Ib. The first edge region Ia and the second edge region Ib are disposed so as to face each other across the central region D in the first direction y. The first edge region Ia is located on the first busbar 4 side. The second edge region Ib is located on the second busbar 5 side.

A pair of gap regions are disposed between the intersection region A and the pair of busbars. Specifically, the pair of gap regions include a first gap region Ja and a second gap region Jb. The first gap region Ja is located on the first busbar 4 side. The second gap region Jb is located on the second busbar 5 side.

In the first edge region Ia and the second edge region Ib, each electrode finger includes a wide portion. The width of the electrode finger in the wide portion is wider than the width of the electrode finger in the central region D. More specifically, a first electrode finger 56 includes a wide portion 56a in the first edge region Ia. The first electrode finger 56 includes a wide portion 56b in the second edge region Ib. Similarly, a second electrode finger 57 includes a wide portion 57a in the first edge region Ia. The second electrode finger 57 includes a wide portion 57b in the second edge region Ib. This causes the acoustic velocity in the first edge region Ia and the second edge region Ib to be lower than the acoustic velocity in the central region D. The width of the electrode finger is the dimension of the electrode finger in the second direction x.

In the first edge region Ia, the plurality of electrode fingers each include a wide portion, causing the average acoustic velocity to be lower from the first edge region Ia to the inner busbar portion 4a of the first busbar 4. A low acoustic velocity region is thus provided in the region covering from the first edge region Ia to the inner busbar portion 4a of the first busbar 4. Similarly, a low acoustic velocity region is provided in the region covering from the second edge region Ib to the inner busbar portion 5a of the second busbar 5. Note that the low acoustic velocity region is a region where the acoustic velocity or the average acoustic velocity is lower than the acoustic velocity in the central region D.

The central region D and a pair of low acoustic velocity regions are arranged in this order from the inner side to the outer side in the first direction y. This makes it possible to establish the piston mode and to reduce or prevent the transverse mode.

At least one electrode finger includes a wide portion in the first edge region Ia and the second edge region Ib. However, it is preferable that the plurality of electrode fingers have the wide portions in the first edge region Ia and the second edge region Ib. It is more preferable that all the electrode fingers include the wide portions. This makes it possible to more reliably establish the piston mode and more reliably reduce or prevent the transverse mode.

In this example embodiment, as in the first example embodiment, a plurality of cavities 4d are provided between the inner busbar portion 4a and the outer busbar portion 4b in the first busbar 4. A plurality of cavities 5d are provided between the inner busbar portion 5a and the outer busbar portion 5b in the second busbar 5. The region of the first busbar 4 where the plurality of cavities 4d are provided is referred to as a first cavity formation region Ka. The region of the second busbar 5 where the plurality of cavities 5d are provided is referred to as a second cavity formation region Kb.

In the first cavity formation region Ka, each connection electrode 4c is provided on the extension line of each first electrode finger 56, and is not provided on the extension line of each second electrode finger 57. A high acoustic velocity region is thus provided in the first cavity formation region Ka. The high acoustic velocity region is a region where the acoustic velocity is higher than the acoustic velocity in the central region D. Similarly, a high acoustic velocity region is provided in the second cavity formation region Kb of the second busbar 5.

The central region D, a pair of low acoustic velocity regions, and a pair of high acoustic velocity regions are arranged in this order from the inner side to the outer side in the first direction y. This makes it possible to more reliably establish the piston mode and more reliably reduce or prevent the transverse mode.

As shown in FIG. 29, in this example embodiment, each reflector has the same configuration as that of the first example embodiment. This makes it possible to prevent an increase in return loss. Note that each reflector may be a reflector having any other configuration according to an example embodiment of the present invention, other than that of the first example embodiment.

In the IDT electrode 53, each busbar does not necessarily have to have any cavity provided therein. The low acoustic velocity region may be provided in the first edge region Ia and the second edge region Ib. In this case, each gap region may define and function as the high acoustic velocity region. However, it is preferable that each busbar includes a cavity formed therein in the IDT electrode 53. In this case, the return loss can be particularly preferably reduced or prevented by the configurations of example embodiments of the present invention.

FIG. 30 is a partially enlarged schematic plan view showing the vicinity of a first busbar and a second busbar in an IDT electrode according to an eleventh example embodiment.

This example embodiment differs from the first example embodiment in that a pair of mass-adding films 69 are provided in a pair of edge regions of the IDT electrode 3. Otherwise, the acoustic wave device according to this example embodiment has the same configuration as that of the acoustic wave device 1 according to the first example embodiment.

One of the pair of mass-adding films 69 is provided in the first edge region Ia. The other mass-adding film 69 is provided in the second edge region Ib. Each mass-adding film 69 has a band-like shape. More specifically, each mass-adding film 69 is provided continuously so as to overlap a plurality of electrode fingers and the region between the electrode fingers in plan view. In this specification, “in plan view” refers to viewing the acoustic wave device from above in a direction perpendicular to the first direction y and the second direction x. More specifically, for example, the first main surface 2a side of the first main surface 2a side and the second main surface 2b side of the piezoelectric substrate 2 is above in a direction perpendicular to the first direction y and the second direction x.

As shown in FIG. 30, the mass-adding film 69 provided in each edge region causes the acoustic velocity in each edge region to be lower than the acoustic velocity in the central region D. A low acoustic velocity region is thus provided in each edge region. This makes it possible to establish a piston mode and to reduce or prevent the transverse mode. The mass-adding film 69 can be made of a dielectric such as tantalum oxide, for example.

In this example embodiment, the mass-adding film 69 is provided on the piezoelectric substrate 2 so as to cover the plurality of electrode fingers. Therefore, the piezoelectric substrate 2, the electrode fingers, and the mass-adding film 69 are laminated in this order in the portion where the mass-adding film 69 and the electrode fingers overlap each other in plan view. However, the piezoelectric substrate 2, the mass-adding film 69, and the electrode fingers may be laminated in this order, for example. Specifically, the mass-adding film 69 may be provided between the piezoelectric substrate 2 and the electrode fingers.

Note that a plurality the mass-adding films 69 may be provided in each edge region. In this case, each mass-adding film 69 may be provided so as to overlap one electrode finger in plan view. The mass-adding film 69 may be provided on the first electrode finger 6 and the second electrode finger 7 in contact therewith, or may be provided with a dielectric film or the like interposed therebetween. In a case where the mass-adding film 69 is not in contact with either of the first electrode finger 6 and the second electrode finger 7, metal may be used as the material of the mass-adding film 69.

In the first edge region Ia and the second edge region Ib, the mass-adding film 69 is provided so as to overlap at least one electrode finger in plan view. It is more preferable that the mass-adding film 69 is provided so as to overlap all the electrode fingers in plan view. This makes it possible to more reliably establish the piston mode and more reliably reduce or prevent the transverse mode.

For example, as in the tenth example embodiment, each electrode finger may have a wide portion. In this case, a low acoustic velocity region may be provided by including the mass-adding film 69.

As shown in FIG. 30, in this example embodiment, each reflector also has the same configuration as that of the first example embodiment. This makes it possible to prevent an increase in return loss. Note that each reflector may be a reflector having another configuration according to an example embodiment of the present invention, other than that of the first example embodiment.

The acoustic wave devices according to the present invention exemplified in the first to eleventh example embodiments are acoustic wave resonators, for example. The acoustic wave resonators according to example embodiments of the present invention may be used in a filter device or the like, for example. In such a case, an acoustic wave element including a plurality of acoustic wave resonators according to one of example embodiments of the present invention can be used as portion of the filter device or the like. An example of an acoustic wave element according to an example embodiment of the present invention including two acoustic wave resonators will be described below.

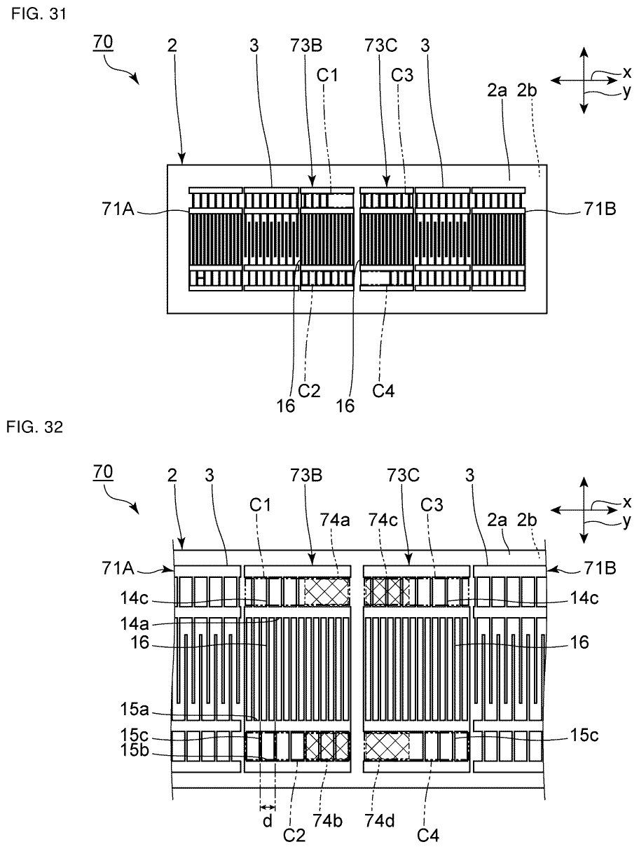

FIG. 31 is a plan view of an acoustic wave element according to a twelfth example embodiment of the present invention.

An acoustic wave element 70 includes a first acoustic wave resonator 71A and a second acoustic wave resonator 71B. The first acoustic wave resonator 71A and the second acoustic wave resonator 71B are each the acoustic wave resonator according to an example embodiment of the present invention. Of the first acoustic wave resonator 71A and the second acoustic wave resonator 71B, at least the first acoustic wave resonator 71A may be the acoustic wave device according to an example embodiment of the present invention.

The first acoustic wave resonator 71A and the second acoustic wave resonator 71B share a piezoelectric substrate 2. The first acoustic wave resonator 71A and the second acoustic wave resonator 71B each include a pair of reflectors and an IDT electrode 3. The IDT electrodes 3 in the first acoustic wave resonator 71A and the second acoustic wave resonator 71B each include the same configuration as that of the IDT electrodes 3 in the acoustic wave device 1 according to the first example embodiment. However, each IDT electrode 3 may have the same configuration as that of the IDT electrode 53 according to the tenth example embodiment, for example.

Each reflector of the first acoustic wave resonator 71A and the second acoustic wave resonator 71B basically has the same configuration as that of the acoustic wave device 1 according to the first example embodiment. Specifically, each reflector includes a pair of reflector busbars and a plurality of reflector electrode fingers 16. The pair of reflector busbars face each other. The plurality of reflector electrode fingers 16 are electrically connected to the pair of reflector busbars. Each reflector busbar of the first acoustic wave resonator 71A and the second acoustic wave resonator 71B includes a plurality of reflector connection electrodes. In each reflector, the plurality of reflector connection electrodes may be directly or indirectly connected to the plurality of reflector electrode fingers 16.

In each of the first acoustic wave resonator 71A and the second acoustic wave resonator 71B, a first direction y is the direction in which the plurality of electrode fingers of the IDT electrode 3 extend, and a second direction x is the direction orthogonal to the first direction y. In each of the first acoustic wave resonator 71A and the second acoustic wave resonator 71B, connection electrode formation regions are each defined in the same manner as in the first example embodiment. However, the configurations of the first acoustic wave resonator 71A and the second acoustic wave resonator 71B differ from the configuration of the acoustic wave device 1 according to the first example embodiment in the metallization ratio in each connection electrode formation region.

The first acoustic wave resonator 71A and the second acoustic wave resonator 71B are adjacent to each other in the second direction x of the first acoustic wave resonator 71A. The second direction x of the first acoustic wave resonator 71A is the same as the second direction x of the second acoustic wave resonator 71B. In this specification, when it is described that the second directions x of both acoustic wave resonators are the same, it includes a case where the angle between the second directions x is equal to or smaller than 1°, for example.

When one of the reflectors of the first acoustic wave resonator 71A is a first reflector 73B and one of the reflectors of the second acoustic wave resonator 71B is a second reflector 73C, the connection electrode formation regions of both are adjacent to each other in the second direction x of the first acoustic wave resonator 71A.

It is assumed in the following description that one connection electrode formation region in the first reflector 73B is a first connection electrode formation region C1 and the other connection electrode formation region is a second connection electrode formation region C2. It is also assumed that one connection electrode formation region in the second reflector 73C is a third connection electrode formation region C3 and the other connection electrode formation region is a fourth connection electrode formation region C4. The first connection electrode formation region C1 in the first reflector 73B and the third connection electrode formation region C3 in the second reflector 73C are adjacent to each other in the second direction x of the first acoustic wave resonator 71A. The second connection electrode formation region C2 in the first reflector 73B and the fourth connection electrode formation region C4 in the second reflector 73C are adjacent to each other in the second direction x of the first acoustic wave resonator 71A.

In this example embodiment, the first connection electrode formation region C1 of the first reflector 73B in the first acoustic wave resonator 71A includes a portion with a different metallization ratio in the second direction x. This makes it possible to prevent an increase in return loss in the first acoustic wave resonator 71A.

Similarly, the fourth connection electrode formation region C4 of the second reflector 73C in the second acoustic wave resonator 71B includes a portion with a different metallization ratio in the second direction x. This makes it possible to prevent an increase in return loss in the second acoustic wave resonator 71B. Therefore, an increase in insertion loss is prevented in a case of using the acoustic wave element 70 in a filter device.

In the first acoustic wave resonator 71A, the metallization ratio is constant in all the connection electrode formation regions of the pair of reflectors other than the first connection electrode formation region C1. However, in the first acoustic wave resonator 71A, the connection electrode formation regions other than the first connection electrode formation region C1 may include portions with different metallization ratios in at least one of the first direction y and the second direction x.

In the second acoustic wave resonator 71B, the metallization ratio is constant in all the connection electrode formation regions of the pair of reflectors other than the fourth connection electrode formation region C4. However, in the second acoustic wave resonator 71B, the connection electrode formation regions other than the fourth connection electrode formation region C4 may include portions with different metallization ratios in at least one of the first direction y and the second direction X.

FIG. 32 is an enlarged plan view showing the vicinity of the first reflector and the second reflector according to the twelfth example embodiment. In FIG. 32, adjacent portions to be described later are indicated by hatching.

The first connection electrode formation region C1 of the first reflector 73B includes a first adjacent portion 74a. The first adjacent portion 74a of the first connection electrode formation region C1 is a portion including an edge portion of the first connection electrode formation region C1 on the second reflector 73C side. The dimension of the first adjacent portion 74a in the second direction x of the first acoustic wave resonator 71A is the dimension d of one period. Similarly, the second connection electrode formation region C2 includes a first adjacent portion 74b. As described above, the dimension d of one period is twice the center-to-center distance in the second direction x between adjacent reflector electrode fingers 16.

The third connection electrode formation region C3 of the second reflector 73C includes a second adjacent portion 74c. The second adjacent portion 74c of the third connection electrode formation region C3 is a portion including an edge portion of the third connection electrode formation region C3 on the first reflector 73B side. The dimension of the second adjacent portion 74c in the second direction x of the second acoustic wave resonator 71B is the dimension d of one period. Similarly, the fourth connection electrode formation region C4 includes a second adjacent portion 74d.

In the first adjacent portion 74a of the first connection electrode formation region C1 in the first reflector 73B, the number of reflector connection electrodes 14c is 0. Therefore, the metallization ratio of the first adjacent portion 74a is 0. In the second adjacent portion 74d of the fourth connection electrode formation region C4 in the second reflector 73C, the number of reflector connection electrodes 15c is 0. Therefore, the metallization ratio of the second adjacent portion 74d is 0.

In the second connection electrode formation region C2 of the first reflector 73B, on the other hand, the metallization ratio is constant. In this example embodiment, the metallization ratio in the second connection electrode formation region C2 is the value obtained by dividing the width w of the reflector connection electrode 14c by the dimension d of one period, where w is the width of the reflector connection electrode 14c. Therefore, the metallization ratio of the first adjacent portion 74b in the second connection electrode formation region C2 is w/d. Similarly, the metallization ratio of the second adjacent portion 74c in the third connection electrode formation region C3 is w/d.

From the above, in the first reflector 73B, the metallization ratio of the first adjacent portion 74a in the first connection electrode formation region C1 is smaller than the metallization ratio of the first adjacent portion 74b in the second connection electrode formation region C2. In the second reflector 73C, the metallization ratio of the second adjacent portion 74c in the third connection electrode formation region C3 is larger than the metallization ratio of the second adjacent portion 74d in the fourth connection electrode formation region C4.

The relationship of the magnitude of the metallization ratio of the first adjacent portion 74b relative to the metallization ratio of the first adjacent portion 74a is different from the relationship of the magnitude of the metallization ratio of the second adjacent portion 74d relative to the metallization ratio of the second adjacent portion 74c. This makes it possible to reduce or prevent the coupling of acoustic waves between the first acoustic wave resonator 71A and the second acoustic wave resonator 71B without increasing the size of the acoustic wave element 70. This will be described in detail with reference to an acoustic wave element in which both acoustic wave resonators are the acoustic wave devices of the comparative example and an example of the related art. Hereinafter, the acoustic wave device of the comparative example may be referred to as an acoustic wave resonator.

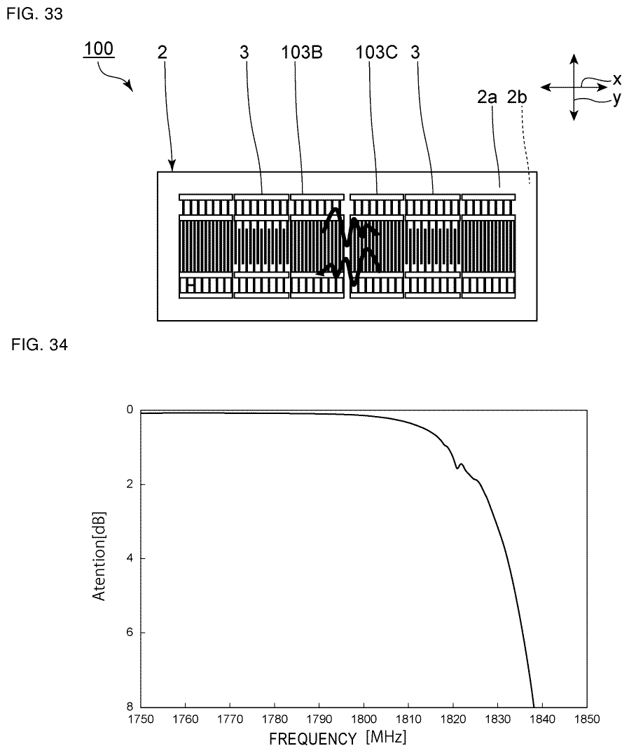

FIG. 33 is a schematic plan view of an acoustic wave element including two acoustic wave resonators of the comparative example. The wavy arrows in FIG. 33 schematically represent acoustic waves excited and propagating in both acoustic wave resonators.

In an acoustic wave element 100, the metallization ratio is constant in all connection electrode formation regions of a reflector 103B and a reflector 103C, which are adjacent to each other in the two acoustic wave resonators. Therefore, a first adjacent portion of the connection electrode formation region in the reflector 103B of one acoustic wave resonator and a second adjacent portion of the connection electrode formation region in the reflector 103C adjacent to the connection electrode formation region have the same metallization ratio. FIG. 34 shows a portion of a pass band of a filter device using this acoustic wave element 100.

FIG. 34 is a graph showing attenuation frequency characteristics near the high-frequency side of the pass band in the filter device using the acoustic wave element including two acoustic wave resonators of the comparative example.

In the attenuation frequency characteristics shown in FIG. 34, ripple occurs at the frequencies on the high-frequency side of the pass band where the attenuation starts to increase. This is caused by the coupling of acoustic waves between one acoustic wave resonator and the other acoustic wave resonator. The ripple caused by the coupling of acoustic waves can occur not only at the frequencies shown in FIG. 34 but also at various frequencies within the pass band.

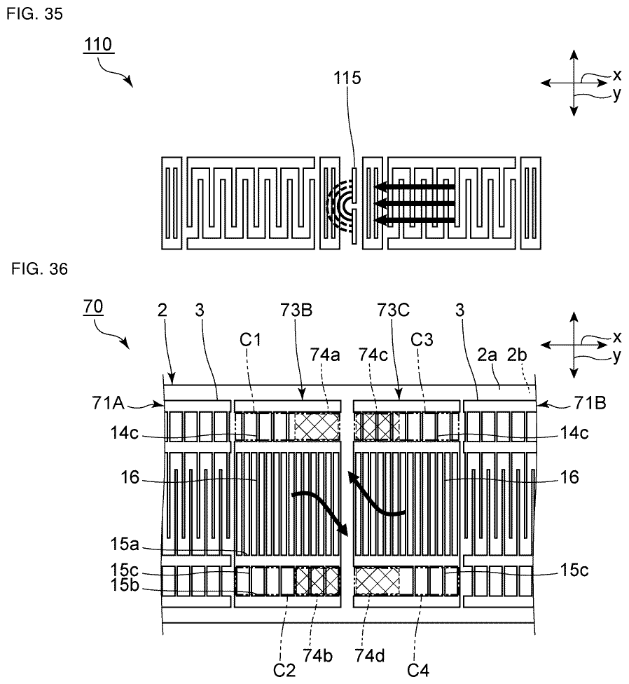

On the other hand, in the example of the related art schematically shown in FIG. 35, a slit pattern 115 is provided between the two acoustic wave resonators. This prevents the from acoustic wave excited in one acoustic wave resonator propagating to the other acoustic wave resonator. However, the slit pattern 115 thus provided increases the size of an acoustic wave element 110.

In the twelfth example embodiment shown in FIG. 32, on the other hand, the coupling of acoustic waves between the first acoustic wave resonator 71A and the second acoustic wave resonator 71B is reduced or prevented without increasing the size of the acoustic wave element 70.

More specifically, the acoustic wave propagation direction is parallel to the second direction x. However, strictly speaking, the direction in which the acoustic wave propagates in the reflector is affected by the configuration of the connection electrode formation region. Specifically, the acoustic wave propagation direction in the reflector includes not only a component of the second direction x but also a component of the first direction y. More specifically, in the reflector, the acoustic wave propagates toward one of the two connection electrode formation regions with a larger metallization ratio.

In this example embodiment, in the first reflector 73B, the metallization ratio of the first adjacent portion 74a in the first connection electrode formation region C1 is smaller than the metallization ratio of the first adjacent portion 74b in the second connection electrode formation region C2. In this case, as schematically shown in FIG. 36, in the first reflector 73B, the acoustic wave propagates toward the second connection electrode formation region C2 as it moves away from the IDT electrode 3 of the first acoustic wave resonator 71A in the second direction x.

Specifically, the acoustic wave excited in the first acoustic wave resonator 71A and propagating to the second acoustic wave resonator 71B propagates toward the fourth connection electrode formation region C4 in the second reflector 73C.

In the second reflector 73C, on the other hand, the metallization ratio of the second adjacent portion 74c in the third connection electrode formation region C3 is larger than the metallization ratio of the second adjacent portion 74d in the fourth connection electrode formation region C4. In this case, in the second reflector 73C, the acoustic wave propagates toward the third connection electrode formation region C3 as it moves away from the IDT electrode 3 of the second acoustic wave resonator 71B in the second direction x.

Specifically, the acoustic wave excited in the second acoustic wave resonator 71B and propagating to the first acoustic wave resonator 71A propagates toward the first connection electrode formation region C1 in the first reflector 73B.

As described above, in this example embodiment, the acoustic wave propagation direction from the first acoustic wave resonator 71A to the second acoustic wave resonator 71B can be different from the acoustic wave propagation direction from the second acoustic wave resonator 71B to the first acoustic wave resonator 71A. This makes it possible to reduce or prevent the coupling of the acoustic waves between the first acoustic wave resonator 71A and the second acoustic wave resonator 71B. In addition, the slit pattern 115 shown in FIG. 35 is not provided in this example embodiment. This can prevent an increase in size of the acoustic wave element 70.

In this example embodiment, the metallization ratio in the first adjacent portion 74a is 0. This allows the acoustic wave toward the second acoustic wave resonator 71B to more reliably propagate toward the fourth connection electrode formation region C4 in the first reflector 73B. Similarly, the metallization ratio in the second adjacent portion 74d is 0. This allows the acoustic wave toward the first acoustic wave resonator 71A to more reliably propagate toward the first connection electrode formation region C1 in the second reflector 73C.

However, the metallization ratios of the first adjacent portion 74a and the second adjacent portion 74d do not have to be 0. For example, in the first reflector 73B, the metallization ratio of the first adjacent portion 74a in the first connection electrode formation region C1 may be not 0 and smaller than the metallization ratio of the first adjacent portion 74b in the second connection electrode formation region C2. Similarly, in the second reflector 73C, the metallization ratio of the second adjacent portion 74d in the fourth connection electrode formation region C4 may be not 0 and smaller than the metallization ratio of the second adjacent portion 74c in the third connection electrode formation region C3.

In this example embodiment, in the first connection electrode formation region C1, the metallization ratio in the first adjacent portion 74a is smaller than the metallization ratio in at least a part other than the first adjacent portion 74a. In the fourth connection electrode formation region C4, the metallization ratio in the second adjacent portion 74d is smaller than the metallization ratio in at least a part other than the second adjacent portion 74d. However, the present invention is not limited thereto.

As shown in FIG. 32, in the first reflector 73B, all the reflector electrode fingers 16 are connected to the inner reflector busbar portion 14a and the inner reflector busbar portion 15a. Each reflector connection electrode 15c is indirectly connected to each reflector electrode finger 16 through the inner reflector busbar portion 15a. However, as in the third example embodiment shown in FIG. 13, for example, only some of all the reflector electrode fingers 16 may be connected to the inner reflector busbar portion 15a. In this case, the reflector connection electrodes 15c may be provided on the respective extension lines of all the reflector electrode fingers 16 connected to the inner reflector busbar portion 15a. The same applies to the second reflector 73C.

Alternatively, the first reflector 73B does not have to have the inner reflector busbar portion 15a provided therein, as in the fourth example embodiment shown in FIG. 15, for example. In this case, the reflector electrode fingers 16 and the reflector connection electrodes 15c may be directly connected. The same applies to the second reflector 73C.

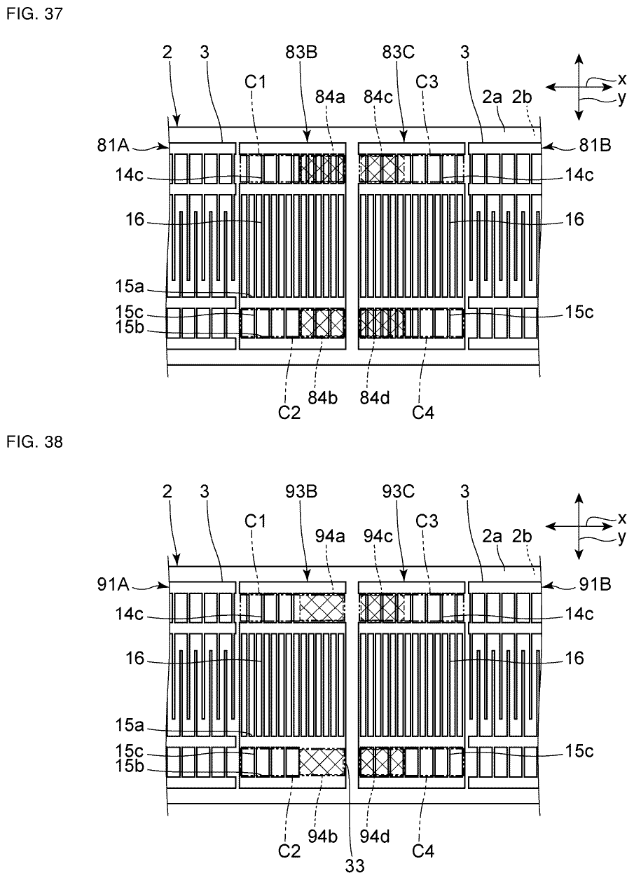

FIG. 37 is an enlarged plan view showing the vicinity of a first reflector and a second reflector according to a thirteenth example embodiment.

This example embodiment differs from the twelfth example embodiment in the metallization ratio of each adjacent portion in a first reflector 83B and each adjacent portion in a second reflector 83C. Otherwise, an acoustic wave element of this example embodiment has the same configuration as that of the acoustic wave element 70 of the twelfth example embodiment.

The metallization ratio of each first adjacent portion in the first reflector 83B and each second adjacent portion in the second reflector 83C is not 0.

In this example embodiment, in the first reflector 83B, the metallization ratio of a first adjacent portion 84a in a first connection electrode formation region C1 is larger than the metallization ratio of a first adjacent portion 84b in a second connection electrode formation region C2. In this case, in the first reflector 83B, the acoustic wave propagates toward the first connection electrode formation region C1 as it moves away from the IDT electrode 3 of the first acoustic wave resonator 81A in the second direction x.

Specifically, the acoustic wave excited in the first acoustic wave resonator 81A and propagating to the second acoustic wave resonator 81B propagates toward the third connection electrode formation region C3 in the second reflector 83C.

In the second reflector 83C, on the other hand, the metallization ratio of a second adjacent portion 84c in the third connection electrode formation region C3 is smaller than the metallization ratio of a second adjacent portion 84d in the fourth connection electrode formation region C4. In this case, in the second reflector 83C, the acoustic wave propagates toward the fourth connection electrode formation region C4 as it moves away from the IDT electrode 3 of the second acoustic wave resonator 81B in the second direction x.

Specifically, the acoustic wave excited in the second acoustic wave resonator 81B and propagating to the first acoustic wave resonator 81A propagates toward the second connection electrode formation region C2 in the first reflector 83B.

As described above, in this example embodiment, the acoustic wave propagation direction from the first acoustic wave resonator 81A to the second acoustic wave resonator 81B can be different from the acoustic wave propagation direction from the second acoustic wave resonator 81B to the first acoustic wave resonator 81A. This makes it possible to reduce or prevent the coupling of acoustic waves between the first acoustic wave resonator 81A and the second acoustic wave resonator 81B without increasing the size of the acoustic wave element.

In addition, in this example embodiment, the first connection electrode formation region C1 of the first reflector 83B in the first acoustic wave resonator 81A includes a portion with a different metallization ratio in the second direction x. Specifically, in the first connection electrode formation region C1, the connection electrode pitch in the first adjacent portion 84a is narrower than the connection electrode pitch at least in a portion other than the first adjacent portion 84a. As a result, in the first connection electrode 1 formation region C1, the metallization ratio in the first adjacent portion 84a is larger than the metallization ratio at least in a portion other than the first adjacent portion 84a. This makes it possible to prevent an increase in return loss in the first acoustic wave resonator 81A.

Similarly, the fourth connection electrode formation region C4 of the second reflector 83C in the second acoustic wave resonator 81B includes a portion with a different metallization ratio in the second direction x. Specifically, in the fourth connection electrode formation region C4, the connection electrode pitch in the second adjacent portion 84d is narrower than the connection electrode pitch at least in a portion other than the second adjacent portion 84d. As a result, in the fourth connection electrode formation region C4, the metallization ratio in the second adjacent portion 84d is larger than the metallization ratio at least in a portion other than the second adjacent portion 84d. This makes it possible to prevent an increase in return loss in the second acoustic wave resonator 81B. Therefore, an increase in insertion loss is prevented in a case of using the acoustic wave element of this example embodiment in a filter device.

In this example embodiment, the portion of the first connection electrode formation region C1 where the connection electrode pitch is wide is farther from the IDT electrode 3 than the portion where the connection electrode pitch is narrow. However, the portion of the first connection electrode formation region C1 where the connection electrode pitch is wide may be closer to the IDT electrode 3 than the portion where the connection electrode pitch is narrow. In each connection electrode formation region other than the first connection electrode formation region C1 in the first acoustic wave resonator 81A, the portion with a wide connection electrode pitch may be farther from the IDT electrode 3 or closer to the IDT electrode 3 than the portion with a narrow connection electrode pitch. The same applies to the second acoustic wave resonator 81B.

As described above in the twelfth example embodiment, the first reflector of the first acoustic wave resonator does not have to include the inner reflector busbar portion. In this case, the connection electrode pitch in a portion of the connection electrode formation region of the first reflector may be wider than the connection electrode pitch in another portion of the connection electrode formation region. The same applies to the second reflector of the second acoustic wave resonator.

In the acoustic wave element according to the present invention, at least the first acoustic wave resonator of the first and second acoustic wave resonators may be the acoustic wave device according to an example embodiment of the present invention. The second acoustic wave resonator does not necessarily have to be the acoustic wave device according to an example embodiment of the present invention. In this case, again, the second acoustic wave resonator may include an IDT electrode and a pair of reflectors separately from the first acoustic wave resonator. As in the acoustic wave device according to an example embodiment of the present invention, each reflector busbar of each reflector in the second acoustic wave resonator may have a connection electrode formation region.

In a case where the second acoustic wave resonator is not the acoustic wave device according to an example embodiment of the present invention, again, the first direction y, the second direction x, and the connection electrode formation region are defined in the same manner as in the acoustic wave device according to an example embodiment of the present invention. The second reflector in the second acoustic wave resonator includes a third connection electrode formation region and a fourth connection electrode formation region. The metallization ratio is constant in each connection electrode formation region of the second acoustic wave resonator that is not an acoustic wave device according to an example embodiment of the present invention. This example will be described in a fourteenth example embodiment.

FIG. 38 is an enlarged plan view showing a first reflector and a second reflector according to the fourteenth example embodiment.

This example embodiment differs from the twelfth example embodiment in the metallization ratio of a first adjacent portion 94b in a second connection electrode formation region C2 of a first reflector 93B and of a second adjacent portion 94d in a fourth connection electrode formation region C4 of a second reflector 93C. Note that, in this example embodiment, a second acoustic wave resonator 91B is not the acoustic wave device according to an example embodiment of the present invention. Otherwise, the acoustic wave element of this example embodiment has the same configuration as that of the acoustic wave element 70 according to the twelfth example embodiment.

The first adjacent portion 94b in the second connection electrode formation region C2 of the first reflector 93B is provided with the same metal film 33 as that of the fifth example embodiment. Specifically, in the first adjacent portion 94b, an inner reflector busbar portion 15a and an outer reflector busbar portion 15b are connected by the metal film 33. The metallization ratio is 1 in the portion of the first adjacent portion 94b where the metal film 33 is provided.

In the first adjacent portion 94a in the first connection electrode formation region C1 of the first reflector 93B, on the other hand, the metallization ratio is 0, as in the twelfth example embodiment. Therefore, the metallization ratio of the first adjacent portion 94a in the first connection electrode formation region C1 is smaller than the metallization ratio of the first adjacent portion 94b in the second connection electrode formation region C2.

On the other hand, the second acoustic wave resonator 91B has the same configuration as that of the acoustic wave device of the comparative example shown in FIG. 3. In the second reflector 93C of the second acoustic wave resonator 91B, the metallization ratio of a second adjacent portion 94c in a third connection electrode formation region C3 is the same as the metallization ratio of a second adjacent portion 94d in a fourth connection electrode formation region C4.

As described above, the relationship of the magnitude of the metallization ratio of the first adjacent portion 94b relative to the metallization ratio of the first adjacent portion 94a is different from the relationship of the magnitude of the metallization ratio of the second adjacent portion 94d relative to the metallization ratio of the second adjacent portion 94c. This makes it possible to make the acoustic wave propagation direction from the first acoustic wave resonator 91A to the second acoustic wave resonator 91B different from the acoustic wave propagation direction from the second acoustic wave resonator 91B to the first acoustic wave resonator 91A. This makes it possible to reduce or prevent the coupling of acoustic waves between the first acoustic wave resonator 91A and the second acoustic wave resonator 91B without increasing the size of the acoustic wave element, as in the twelfth example embodiment.

In addition, each first adjacent portion of the first reflector 93B in the first acoustic wave resonator 91A includes a portion with a different metallization ratio in the second direction x. This makes it possible to prevent an increase in return loss in the first acoustic wave resonator 91A. Therefore, an increase in insertion loss is prevented in a case of using the acoustic wave element of this example embodiment in a filter device.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate;
an IDT electrode on the piezoelectric substrate and including a first busbar and a second busbar facing each other, and a plurality of first electrode fingers and a plurality of second electrode fingers interdigitated with each other; and
a pair of reflectors on the piezoelectric substrate and facing each other across the IDT electrode in a second direction, where a first direction is a direction in which the plurality of first electrode fingers and the plurality of second electrode fingers extend and the second direction is a direction orthogonal to the first direction; wherein
the plurality of first electrode fingers each include a first base end connected to the first busbar, and the plurality of second electrode fingers each include a second base end connected to the second busbar;
in the IDT electrode, a pair of regions outward of first and second base ends of the first and second electrode fingers in the first direction are a pair of outer regions, and regions extending from the pair of outer regions in the second direction are a pair of extended outer regions;
each of the reflectors includes a pair of reflector busbars facing each other and a plurality of reflector electrode fingers electrically connected to the pair of reflector busbars;
each of the reflector busbars includes a plurality of reflector connection electrodes provided in a portion of the reflector located in one of the extended outer regions and directly or indirectly connected to the plurality of reflector electrode fingers;
a region of the reflector extending in the second direction where the plurality of reflector connection electrodes are located is a connection electrode formation region; and when a dimension of one period is twice a center-to-center distance in the second direction between adjacent ones of the reflector electrode fingers, and a ratio of a portion of the piezoelectric substrate covered with a metal of the reflector on a virtual line of the dimension of one period extending in the second direction is a metallization ratio, the connection electrode formation region of at least one of the reflector busbars of at least one of the reflectors includes a portion where the metallization ratio is different in at least one of the first direction and the second direction.

2. The acoustic wave device according to claim 1, wherein the connection electrode formation region in each of the reflector busbars of each of the reflectors includes a portion where the metallization ratio is different in at least one of the first direction and the second direction.

3. The acoustic wave device according to claim 1, wherein
the reflector busbar includes an inner reflector busbar portion and an outer reflector busbar portion, the inner reflector busbar portion being located on an inner side in the first direction than the outer reflector busbar portion;
at least some of all the reflector electrode fingers are indirectly connected to the plurality of reflector connection electrodes through the inner reflector busbar portion; and
a connection electrode pitch in a portion of the connection electrode formation region is wider than the connection electrode pitch in another portion of the connection electrode formation region, where the connection electrode pitch is a center-to-center distance in the second direction between adjacent ones of the reflector connection electrodes.

4. The acoustic wave device according to claim 3, wherein all the reflector electrode fingers are connected to the inner reflector busbar portion.

5. The acoustic wave device according to claim 3, wherein only some of all the reflector electrode fingers are connected to the inner reflector busbar portion.

6. The acoustic wave device according to claim 5, wherein the reflector connection electrodes are provided on extension lines of all the reflector electrode fingers connected to the inner reflector busbar portion.

7. The acoustic wave device according to claim 4, wherein a portion of the connection electrode formation region where the connection electrode pitch is wide is farther from the IDT electrode than a portion of the connection electrode formation region where the connection electrode pitch is narrow.

8. The acoustic wave device according to claim 4, wherein a portion of the connection electrode formation region where the connection electrode pitch is wide is closer to the IDT electrode than a portion of the connection electrode formation region where the connection electrode pitch is narrow.

9. The acoustic wave device according to claim 1, wherein the plurality of reflector electrode fingers and the plurality of reflector connection electrodes are directly connected; and
a connection electrode pitch in a portion of the connection electrode formation region is wider than the connection electrode pitch in another portion of the connection electrode formation region, where the connection electrode pitch is a center-to-center distance in the second direction between adjacent ones of the reflector connection electrodes.

10. The acoustic wave device according to claim 1, wherein
the reflector busbar includes an inner reflector busbar portion and an outer reflector busbar portion, the inner reflector busbar portion being located on an inner side in the first direction than the outer reflector busbar portion; and
the inner reflector busbar portion and the outer reflector busbar portion are connected by a metal film in a portion of the connection electrode formation region, and the metallization ratio is 1 in the portion where the metal film is provided.

11. The acoustic wave device according to claim 1, wherein
the reflector busbar includes an inner reflector busbar portion and an outer reflector busbar portion, the inner reflector busbar portion being located on an inner side in the first direction than the outer reflector busbar portion;
the plurality of reflector electrode fingers are indirectly connected to the plurality of reflector connection electrodes through the inner reflector busbar portion;
all of the reflector electrode fingers are connected to the inner reflector busbar portion;
the reflector busbar includes a plurality of dummy electrode fingers located between the plurality of reflector connection electrodes and extending in the first direction; and
the plurality of dummy electrode fingers each include one end connected to the outer reflector busbar portion and each include another end facing the inner reflector busbar portion across a gap.

12. The acoustic wave device according to claim 1, wherein
the reflector busbar includes an inner reflector busbar portion and an outer reflector busbar portion, the inner reflector busbar portion being located on an inner side in the first direction than the outer reflector busbar portion;
the plurality of reflector electrode fingers are indirectly connected to the plurality of reflector connection electrodes through the inner reflector busbar portion;
all of the reflector electrode fingers are connected to the inner reflector busbar portion;
the reflector busbar includes a plurality of dummy electrode fingers located between the plurality of reflector connection electrodes and extending in the first direction; and
the plurality of dummy electrode fingers each include one end connected to the inner reflector busbar portion and each include another end facing the outer reflector busbar portion across a gap.

13. The acoustic wave device according to claim 11, wherein the plurality of dummy electrode fingers all have a same length.

14. The acoustic wave device according to claim 11, wherein a length of at least one of the plurality of dummy electrode fingers is different from a length of other dummy electrode fingers.

15. The acoustic wave device according to claim 14, wherein the dummy electrode fingers provided at positions farther from the IDT electrode in the second direction have a longer length.

16. The acoustic wave device according to claim 1, wherein
a region where adjacent ones of the first electrode fingers and the second electrode fingers overlap each other when the IDT electrode is viewed in the second direction is an intersection region including a central region and a pair of edge regions facing each other across the central region in the first direction; and
a low acoustic velocity region is provided in the pair of edge regions, in which an acoustic velocity is lower than an acoustic velocity in the central region.

17. The acoustic wave device according to claim 16, wherein the low acoustic velocity region is provided in the pair of edge regions by at least one electrode finger with a wide portion that is wider than a width in the central region.

18. The acoustic wave device according to claim 16, wherein the low acoustic velocity region includes a mass-adding film provided in the pair of edge regions so as to overlap at least one electrode finger in plan view.

19. An acoustic wave element comprising:
a first acoustic wave resonator that is the acoustic wave device according to claim 3; and
a second acoustic wave resonator; wherein
the second acoustic wave resonator shares the piezoelectric substrate with the first acoustic wave resonator;
the second acoustic wave resonator includes an IDT electrode including a plurality of electrode fingers provided on the piezoelectric substrate separately from the first acoustic wave resonator, and a pair of reflectors provided on the piezoelectric substrate so as to face each other across the IDT electrode;
each of the reflectors of the second acoustic wave resonator includes a pair of reflector busbars facing each other and a plurality of reflector electrode fingers electrically connected to the pair of reflector busbars;
each of the reflector busbars of the second acoustic wave resonator includes a plurality of reflector connection electrodes directly or indirectly connected to the plurality of reflector electrode fingers;
in the second acoustic wave resonator, when a first direction is a direction in which the plurality of electrode fingers of the IDT electrode extend and a second direction is a direction orthogonal to the first direction, a region of the reflector of the second acoustic wave resonator extending in the second direction where the plurality of reflector connection electrodes are located is a connection electrode formation region;
when one of the reflectors of the first acoustic wave resonator is a first reflector, one of the reflectors of the second acoustic wave resonator is a second reflector, one of the connection electrode formation regions of the first reflector is a first connection electrode formation region, another of the connection electrode formation regions of the first reflector is a second connection electrode formation region, one of the connection electrode formation regions of the second reflector is a third connection electrode formation region, and another of the connection electrode formation regions of the second reflector is a fourth connection electrode formation region, the first connection electrode formation region and the third connection electrode formation region are adjacent to each other in the second direction of the first acoustic wave resonator, and the second connection electrode formation region and the fourth connection electrode formation region are adjacent to each other in the second direction of the first acoustic wave resonator;
each of the connection electrode formation regions of the first reflector includes a first adjacent portion that is a portion including an edge portion on a second reflector side in the connection electrode formation region and a dimension thereof in the second direction of the first acoustic wave resonator is the dimension of one period, and each of the connection electrode formation regions of the second reflector includes a second adjacent portion that is a portion including an edge portion on a first reflector side in the connection electrode formation region and a dimension thereof in the second direction of the second acoustic wave resonator is a dimension of one period; and
a relationship of magnitude of the metallization ratio of the first adjacent portion in the second connection electrode formation region to the metallization ratio of the first adjacent portion in the first connection electrode formation region in the first reflector is different from a relationship of magnitude of the metallization ratio of the second adjacent portion in the fourth connection electrode formation region to the metallization ratio of the second adjacent portion in the third connection electrode formation region in the second reflector.

20. The acoustic wave element according to claim 19, wherein
in the first reflector, the metallization ratio of the first adjacent portion in the first connection electrode formation region is smaller than the metallization ratio of the first adjacent portion in the second connection electrode formation region; and
the metallization ratio of the first adjacent portion is smaller than the metallization ratio of at least a portion other than the first adjacent portion in the first connection electrode formation region.

21. The acoustic wave element according to claim 20, wherein a number of the reflector connection electrodes provided in the first adjacent portion is 0 in the first connection electrode formation region of the first reflector.

22. The acoustic wave element according to claim 20, wherein
in the second reflector, the metallization ratio of the second adjacent portion in the third connection electrode formation region is larger than the metallization ratio of the second adjacent portion in the fourth connection electrode formation region; and
a number of the reflector connection electrodes provided in the second adjacent portion is 0 in the fourth connection electrode formation region of the second reflector.

23. The acoustic wave element according to claim 20, wherein
the reflector busbar in the first reflector includes an inner reflector busbar portion and an outer reflector busbar portion, the inner reflector busbar portion being located on an inner side in the first direction than the outer reflector busbar portion; and
in the first adjacent portion of the second connection electrode formation region in the first reflector, the inner reflector busbar portion and the outer reflector busbar portion are connected by a metal film, and the metallization ratio is 1 in a portion where the metal film is provided.

24. The acoustic wave element according to claim 19, wherein
in the first reflector, the metallization ratio of the first adjacent portion in the first connection electrode formation region is larger than the metallization ratio of the first adjacent portion in the second connection electrode formation region; and
in the first connection electrode formation region of the first reflector, a connection electrode pitch in the first adjacent portion is narrower than the connection electrode pitch in at least a portion other than the first adjacent portion, where the connection electrode pitch is a center-to-center distance in the second direction between adjacent ones of the reflector connection electrodes.
